(19) United States
(12) Patent Application Publication
(10) Pub. No.: US 2026/0156954 A1
(43) Pub. Date: Jun. 4, 2026

(54) LIGHT DETECTING DEVICE AND ELECTRONIC APPARATUS

(71) Applicant: SONY SEMICONDUCTOR SOLUTIONS CORPORATION, KANAGAWA (JP)

(72) Inventor: AKIRA MATSUMOTO, KANAGAWA (JP)

(21) Appl. No.: 19/123,027

(22) PCT Filed: Sep. 4, 2023
(86) PCT No.: PCT/JP2023/032280

§ 371 Date: Apr. 21, 2025

(30) Foreign Application Priority Data
Oct. 26, 2022 (JP) 2022-171365

(51) Int. Cl. H10F 39/00; H10F 39/18

(52) U.S. Cl. CPC H10F 39/8037; H10F 39/014; H10F 39/182; H10F 39/807; H10F 39/809

(57) ABSTRACT

Provided is a light detecting device that can reduce difficulty in arrangement of transfer gates and charge retaining sections caused by reduction in pixel size. Specifically, the light detecting device includes a semiconductor substrate, a trench section that partitions the semiconductor substrate into multiple element regions, a photoelectric converting section that is formed in each element region and generates and stores charge according to a light reception amount, a charge retaining section that is formed in each element region and retains charge generated in the photoelectric converting section, and a transfer transistor that transfers, to the charge retaining section, charge stored in the photoelectric converting section. In addition, the charge retaining section is formed to reach a predetermined depth in the element region from a first surface of the element region that is a surface opposite to a light incidence surface of the element region. Further, the transfer transistor has a gate electrode that continuously covers at least a part of the first surface of the element region excluding a first region that is on the first surface and is a region where the charge retaining section is formed, and at least a part of a second surface that is a surface of the element region on a side of the trench section.

### TECHNICAL FIELD

The present technology (technology according to the present disclosure) relates to a light detecting device and an electronic apparatus.

### BACKGROUND ART

Conventionally, for example, light detecting devices including a first substrate having photoelectric converting sections, transfer transistors, and charge retaining sections (FD: Floating Diffusions) and a second substrate that is stacked on the first substrate and has pixel transistors other than the transfer transistors have been proposed (see PTL 1, for example). By arranging, in the light detecting device described in PTL 1, photoelectric converting sections, transfer transistors, and FDs on a substrate which is different from a substrate on which pixel transistors other than the transfer transistors are arranged, regions are secured for these and pixel characteristics can be maintained even if pixel sizes are miniaturized.

### CITATION LIST

### Patent Literature

### [PTL 1]

PCT Patent Publication No. WO2020/121725

### SUMMARY

### Technical Problem

However, there is a possibility that the arrangement of FDs and gate electrodes (transfer gates) of transfer transistors in the light detecting device described in PTL 1 becomes difficult as pixel sizes are more miniaturized.

An object of the present disclosure is to provide a light detecting device and an electronic apparatus that can reduce difficulty in arrangement of transfer gates and charge retaining sections caused by reduction in pixel size.

### Solution to Problem

A light detecting device of the present disclosure includes, as the gist thereof, (a) a semiconductor substrate, (b) a trench section that partitions the semiconductor substrate into multiple element regions, (c) a photoelectric converting section that is formed in each element region and generates and stores charge according to a light reception amount, (d) a charge retaining section that is formed in each element region and retains charge generated in the photoelectric converting section, and (e) a transfer transistor that transfers, to the charge retaining section, charge stored in the photoelectric converting section, in which (f) the charge retaining section is formed to reach a predetermined depth in the element region from a first surface of the element region that is a surface opposite to a light incidence surface of the element region, and (g) the transfer transistor has a gate electrode that continuously covers at least a part of the first surface of the element region excluding a first region that is on the first surface and is a region where the charge retaining section is formed, and at least a part of a second surface that is a surface of the element region on a side of the trench section.

An electronic apparatus of the present disclosure includes, as the gist thereof, a light detecting device including (a) a semiconductor substrate, (b) a trench section that partitions the semiconductor substrate into multiple element regions, (c) a photoelectric converting section that is formed in each element region and generates and stores charge according to a light reception amount, (d) a charge retaining section that is formed in each element region and retains charge generated in the photoelectric converting section, and (e) a transfer transistor that transfers, to the charge retaining section, charge stored in the photoelectric converting section, (f) the charge retaining section being formed to reach a predetermined depth in the element region from a first surface of the element region that is a surface opposite to a light incidence surface of the element region, and (g) the transfer transistor having a gate electrode that continuously covers at least a part of the first surface of the element region excluding a first region that is on the first surface and is a region where the charge retaining section is formed, and at least a part of a second surface that is a surface of the element region on a side of the trench section.

### BRIEF DESCRIPTION OF DRAWINGS

FIG. 1 is a figure depicting an overall configuration of a solid-state imaging device according to a first embodiment.

FIG. 2 is a figure depicting a circuit configuration of a pixel.

FIG. 3 is a figure depicting a cross-sectional configuration of the solid-state imaging device taken along a line A-A in FIG. 1.

FIG. 4 is a figure depicting a cross-sectional configuration of the solid-state imaging device taken along a line B-B in FIG. 3.

FIG. 5 is a figure depicting a state of connection between FDs and pixel transistors.

FIG. 6 is a figure depicting a planar configuration of gate electrodes taken along a line C-C in FIG. 3.

FIG. 7 is a perspective view depicting configurations of an element region and a gate electrode.

FIG. 8 is a figure depicting operation of the solid-state imaging device.

FIG. 9 is a figure depicting a planar configuration of a well electrode taken along a line D-D in FIG. 3.

FIG. 10A is a figure depicting a gate electrode production method.

FIG. 10B is a figure depicting the gate electrode production method.

FIG. 10C is a figure depicting the gate electrode production method.

FIG. 10D is a figure depicting the gate electrode production method.

FIG. 10E is a figure depicting the gate electrode production method.

FIG. 10F is a figure depicting the gate electrode production method.

FIG. 11 is a figure depicting a planar configuration of gate electrodes according to a modification example.

FIG. 12 is a figure depicting a cross-sectional configuration of gate electrodes taken along a line E-E in FIG. 11.

FIG. 13 is a figure depicting a planar configuration of gate electrodes according to a modification example.

FIG. 14 is a figure depicting a planar configuration of gate electrodes according to a modification example.

FIG. 15 is a figure depicting a planar configuration of gate electrodes according to a modification example.

FIG. 16 is a figure depicting a planar configuration of gate electrodes according to a modification example.

FIG. 17 is a figure depicting a planar configuration of gate electrodes according to a modification example.

FIG. 18 is a figure depicting a planar configuration of gate electrodes according to a modification example.

FIG. 19 is a figure depicting a planar configuration of gate electrodes according to a modification example.

FIG. 20 is a figure depicting a planar configuration of gate electrodes according to a modification example.

FIG. 21 is a figure depicting a planar configuration of gate electrodes according to a modification example.

FIG. 22 is a figure depicting a planar configuration of gate electrodes according to a modification example.

FIG. 23 is a figure depicting a cross-sectional configuration of the solid-state imaging device according to a modification example.

FIG. 24 is a figure depicting a cross-sectional configuration of the solid-state imaging device according to a modification example.

FIG. 25 is a figure depicting a planar configuration of gate electrodes according to the modification example.

FIG. 26 is a figure depicting a planar configuration of gate electrodes according to a modification example.

FIG. 27 is a figure depicting a planar configuration of gate electrodes according to a modification example.

FIG. 28 is a figure depicting a planar configuration of gate electrodes according to a modification example.

FIG. 29 is a figure depicting a planar configuration of gate electrodes according to a modification example.

FIG. 30 is a figure depicting a cross-sectional configuration of the solid-state imaging device according to a modification example.

FIG. 31 is a figure depicting a cross-sectional configuration of the solid-state imaging device according to a modification example.

FIG. 32 is a figure depicting a cross-sectional configuration of the solid-state imaging device according to a modification example.

FIG. 33 is a figure depicting a cross-sectional configuration of the solid-state imaging device according to a modification example.

FIG. 34 is a figure depicting an overall configuration of an electronic apparatus according to a second embodiment.

### DESCRIPTION OF EMBODIMENTS

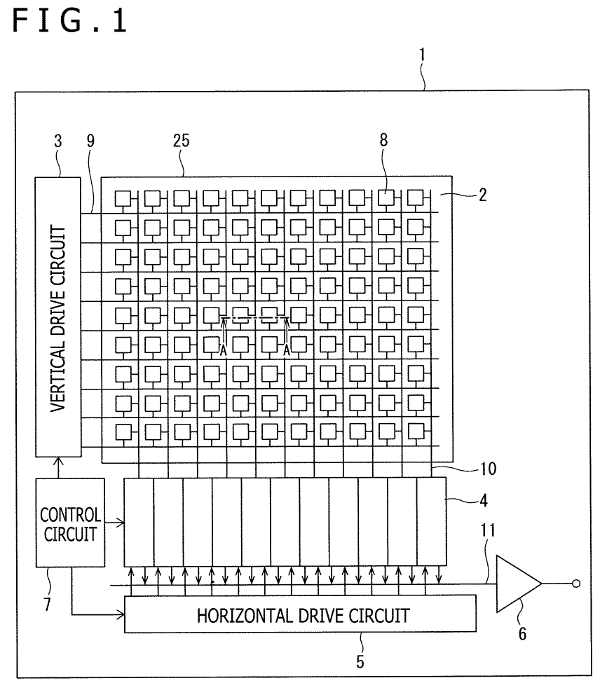

Hereinbelow, examples of a light detecting device and an electronic apparatus according to embodiments of the present disclosure are explained with reference to FIG. 1 to FIG. 34. The embodiments of the present disclosure are explained in the following order. Note that the present disclosure is not limited to the following examples. In addition, advantages described in the present specification are illustrated as examples, advantages of the present disclosure are not limited to them, and there may be other advantages.
1. First Embodiment: Solid-State Imaging Device
   1-1 Overall Configuration of Solid-State Imaging Device
   1-2 Circuit Configuration of Pixels
   1-3 Configurations of Main Sections
   1-4 Gate Electrode Production Method
   1-5 Modification Examples
2. Second Embodiment: Example of Application to Electronic Apparatus

### 1. First Embodiment

### 1-1 Overall Configuration of Solid-State Imaging Device

A solid-state imaging device 1 (a “light detecting device” in a broad sense) according to a first embodiment of the present disclosure is explained. FIG. 1 is a figure depicting an overall configuration of the solid-state imaging device 1 according to the first embodiment.

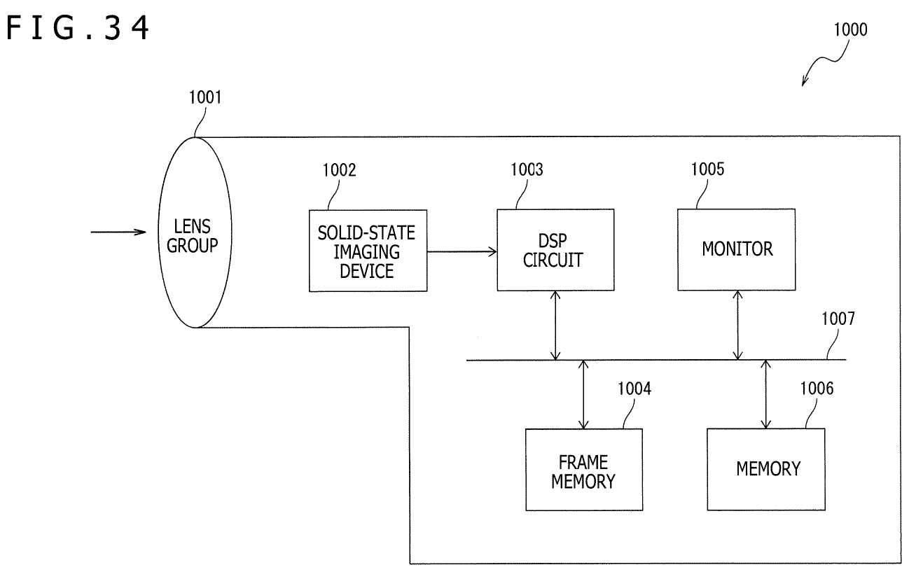

The solid-state imaging device 1 in FIG. 1 is a back-illuminated CMOS (Complementary Metal Oxide Semiconductor) image sensor. As depicted in FIG. 34, the solid-state imaging device 1 (1002) takes in image light (incident light) from a subject via a lens group 1001, converts light amounts of the incident light whose image has been formed on an imaging plane, into electric signals pixel by pixel, and outputs the electric signals as pixel signals.

As depicted in FIG. 1, the solid-state imaging device 1 includes a pixel region 2, a vertical drive circuit 3, column signal processing circuits 4, a horizontal drive circuit 5, an output circuit 6, and a control circuit 7.

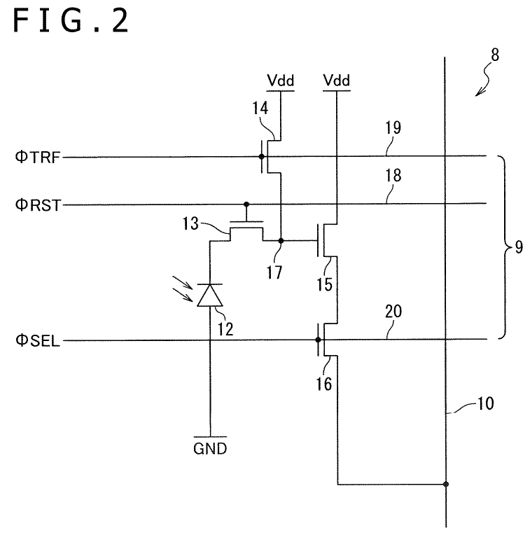

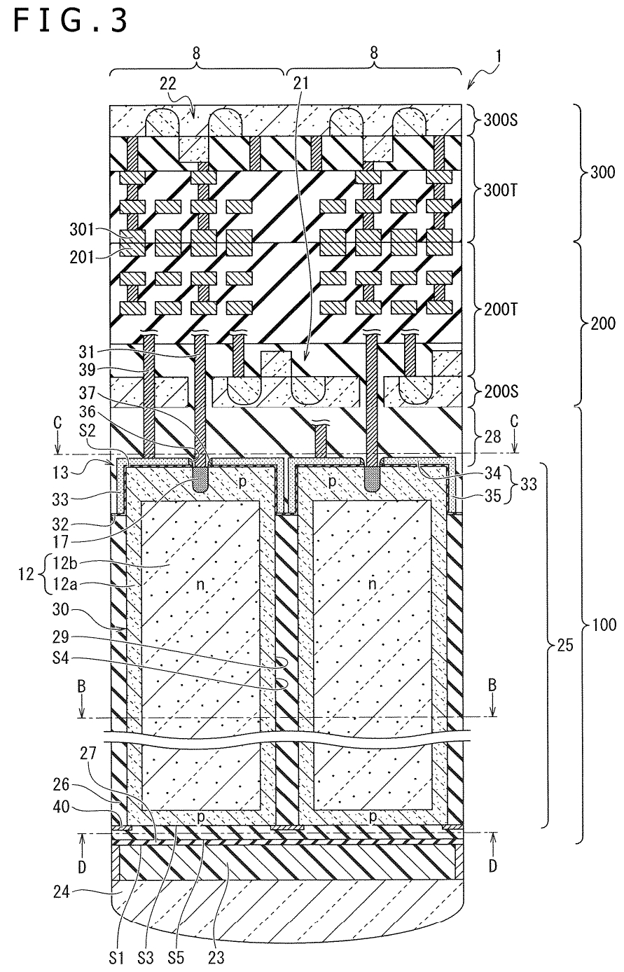

The pixel region 2 has multiple pixels 8 arranged in a two-dimensional array. Each pixel 8 has a photoelectric converting section 12 depicted in FIG. 2 and FIG. 3 and multiple pixel transistors. As the multiple pixel transistors, for example, a transfer transistor 13, a reset transistor 14, an amplification transistor 15, and a selection transistor 16 can be used (see FIG. 2).

For example, the vertical drive circuit 3 is configured using a shift register. The vertical drive circuit 3 sequentially outputs selection pulses oSEL (see FIG. 2) to pixel driving wires 9, sequentially selects respective pixels 8 in the pixel region 2 row by row, and outputs pixel signals of the selected pixels 8 to the column signal processing circuits 4 through vertical signal lines 10. The pixel signals are signals obtained from charge generated in the photoelectric converting sections 12.

For example, each column signal processing circuit 4 is arranged for a column of pixels 8, and performs signal processing on respective pixel signals output from pixels 8 in each row, pixel-column by pixel-column. As the signal processing, for example, CDS (Correlated Double Sampling) for removing fixed pattern noise unique to pixels and AD (Analog Digital) conversion can be used.

For example, the horizontal drive circuit 5 is configured using a shift register. The horizontal drive circuit 5 sequentially outputs horizontal scanning pulses to the column signal processing circuits 4, sequentially selects each of the column signal processing circuits 4, and causes the selected column signal processing circuits 4 to output signal-processed pixel signals to a horizontal signal line 11.

The output circuit 6 performs signal processing on pixel signals that are sequentially output from each of the column signal processing circuits 4 through the horizontal signal line 11, and outputs the pixel signals. As the signal processing, for example, various types of digital signal processing such as buffering, black level adjustment, and column-wise variation correction can be used.

The control circuit 7 generates clock signals and control signals that serve as references for operation of the vertical drive circuit 3, the column signal processing circuits 4, the horizontal drive circuit 5, and the like, on the basis of vertical synchronization signals, horizontal synchronization signals, and master clock signals (not depicted). Further, the control circuit 7 outputs the generated clock signals and control signals to the vertical drive circuit 3, the column signal processing circuits 4, the horizontal drive circuit 5, and the like.

### 1-2 Circuit Configuration of Pixels

Next, a circuit configuration of each pixel 8 is explained. FIG. 2 is a figure depicting a circuit configuration of a pixel 8.

As depicted in FIG. 2, each pixel 8 has the photoelectric converting section 12, four pixel transistors (the transfer transistor 13, the reset transistor 14, the amplification transistor 15, the selection transistor 16), and a floating diffusion (hereinafter, also called an “FD 17”). As the transfer transistor 13, the reset transistor 14, the amplification transistor 15, and the selection transistor 16, for example, n-channel MOS transistors can be adopted. In addition, the FD 17 is a charge retaining section that retains charge (e.g., electrons) generated in the photoelectric converting section 12. For example, an n-type semiconductor region formed by ion implantation of n-type impurities at high concentration can be adopted. In addition, as the pixel driving wires 9, for example, pixels 8 in the same row are provided with a transfer line 18, a reset line 19, and a selection line 20 that are shared by the pixels 8 in the same row. One end of the transfer line 18, one end of the reset line 19, and one end of the selection line 20 are each connected to the vertical drive circuit 3.

The photoelectric converting section 12 has an anode electrode electrically connected to a supply source of predetermined potential (e.g., the ground) and has a cathode electrode connected to a gate electrode of the amplification transistor 15 via the transfer transistor 13. Further, the photoelectric converting section 12 generates charge according to a light reception amount.

The transfer transistor 13 is connected between the cathode electrode of the photoelectric converting section 12 and the FD 17. A transfer pulse oTRF whose high level (e.g., Vdd) is regarded active (hereinafter, also called “High-active”) is applied to a gate electrode of the transfer transistor 13 via the transfer line 18. When the transfer pulse oTRF is applied to the gate electrode, the transfer transistor 13 is turned on, and the charge stored in the photoelectric converting section 12 is transferred to the FD 17.

The reset transistor 14 has a drain electrode connected to a pixel power supply Vdd and has a source electrode connected to the FD 17. A High-active reset pulse (RST is applied to a gate electrode of the reset transistor 14 via the reset line 19 prior to the charge transfer from the photoelectric converting section 12 to the FD 17 by the transfer transistor 13. When the reset pulse VRST is applied to the gate electrode, the reset transistor 14 is turned on, drains the charge stored in the FD 17 to the pixel power supply Vdd, and resets the FD 17.

The amplification transistor 15 has the gate electrode connected to the FD 17 and has a drain electrode connected to the pixel power supply Vdd. Further, after the resetting, the amplification transistor 15 outputs, as a pixel signal, a signal according to the potential of the FD 17 after the charge transfer by the transfer transistor 13.

The selection transistor 16 has a drain electrode connected to a source electrode of the amplification transistor 15 and has a source electrode connected to the vertical signal line 10. A High-active selection pulse oSEL is applied to a gate electrode of the selection transistor 16 via the selection line 20. When the selection pulse OSEL is applied to the gate electrode, the selection transistor 16 is turned on and outputs, to the vertical signal line 10, the pixel signal output from the amplification transistor 15.

### 1-3 Configurations of Main Sections

Next, a specific structure of the solid-state imaging device 1 is explained. FIG. 3 is a figure depicting a cross-sectional configuration of the solid-state imaging device 1 taken along a line A-A in FIG. 1.

As depicted in FIG. 3, the solid-state imaging device 1 has a configuration in which a first substrate 100, a second substrate 200, and a third substrate 300 are stacked in this order from the side of a light incidence surface of the solid-state imaging device 1.

The first substrate 100 has photoelectric converting sections 12, transfer transistors 13, and FDs 17. In addition, the second substrate 200 has pixel transistors 21 that read out charge retained in the FDs 17. For example, examples of the pixel transistors 21 that read out charge include the reset transistor 14, the amplification transistor 15, and the selection transistor 16 (see FIG. 2). In addition, the third substrate 300 has logic circuits 22 that process pixel signals obtained from the charge read out on the second substrate 200. For example, examples of the logic circuits 22 include the vertical drive circuit 3, the column signal processing circuits 4, the horizontal drive circuit 5, the output circuit 6, and the control circuit 7 (see FIG. 1). In addition, color filters 23 and microlenses 24 are stacked in this order on the side of the light incidence surface (hereinafter, also called the “rear surface S1”) of the first substrate 100. FIG. 3 illustrates a case where one color filter 23 and one microlens 24 are arranged for four photoelectric converting sections 12 arrayed in a 2×2 array.

In addition, the first substrate 100 includes a semiconductor substrate 25 and a wiring layer 28. In addition, the second substrate 200 includes a semiconductor layer 200S and a wiring layer 200T. In addition, the third substrate 300 includes a semiconductor layer 300S and a wiring layer 300T. The semiconductor substrate 25, the wiring layer 28, the semiconductor layer 200S, the wiring layer 200T, the wiring layer 300T, and the semiconductor layer 300S are arranged in this order. For example, the first substrate 100 and the second substrate 200 (i.e., the FDs 17 and the pixel transistors 21) are electrically connected to each other by electrodes (contacts 31) extending in a thickness direction of the first substrate 100. In addition, for example, the second substrate 200 and the third substrate 300 are electrically connected to each other via electrode pads 201 exposed on a front surface of the wiring layer 200T and electrode pads 301 exposed on a front surface of the wiring layer 300T. As the material of the electrode pads 201, for example, copper (Cu) or aluminum (Al) can be adopted.

Next, a specific structure of the first substrate 100 is explained.

As depicted in FIG. 3, the first substrate 100 has a configuration in which the semiconductor substrate 25, an insulating film 26, and a flattening film 27 are stacked in this order from the side of the second substrate 200. In addition, the wiring layer 28 is arranged on a surface (hereinafter, also called the “front surface S2”) of the semiconductor substrate 25 on the side of the second substrate 200.

For example, the semiconductor substrate 25 is configured using a silicon (Si) substrate. On the semiconductor substrate 25, a photoelectric converting section 12 is formed in each of regions of respective pixels 8. That is, on the semiconductor substrate 25, multiple photoelectric converting sections 12 are arranged in a two-dimensional array. Each photoelectric converting section 12 has a first-conductivity-type (e.g., p-type) well region 12a, and a second-conductivity-type region 12b that is of a second conductivity type (a conductivity type opposite to the first conductivity type; for example, n-type) and forms a pn junction with the well region 12a. The well region 12a is formed continuously on the whole of side wall surfaces S4 (“second surfaces” in a broad sense) of a trench section 29, the whole of a light incidence surface (hereinafter, also called the “rear surface S3”) of an element region 30, and the whole of the front surface S2 of the element region 30. The well region 12a is thus exposed on each of the whole on the side of the rear surface S3 of the element region 30, the whole on the sides of the side wall surfaces S4 of the element region 30, and the whole on the side of the front surface S2 (a “first surface” in a broad sense; a surface opposite to the light incidence surface) of the element region 30. In addition, the thickness of a portion of the well region 12a which portion is positioned on the side of the front surface S2 of the element region 30 is greater than the thickness of a portion of the well region 12a which portion is positioned on the side of the rear surface S3. In addition, the second-conductivity-type region 12b is formed in a region on a center side in the element region 30 such that the second-conductivity-type region 12b contacts the well region 12a. The photoelectric converting section 12 forms a photodiode by the pn junction between the well region 12a and the second-conductivity-type region 12b and generates charge (e.g., electrons) according to the light reception amount. In addition, the photoelectric converting section 12 stores charge generated by photoelectric conversion, in an electrostatic capacitance generated at the pn junction.

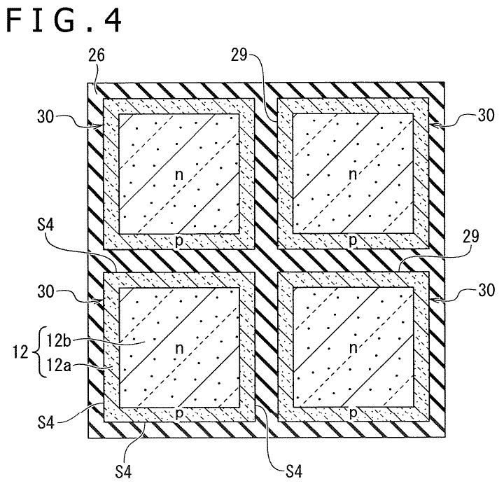

In addition, in the semiconductor substrate 25, the trench section 29 is formed in all regions between adjacent photoelectric converting sections 12. That is, the trench section 29 is formed in such a grid that surrounds the respective photoelectric converting sections 12. The trench section 29 penetrates the semiconductor substrate 25 from the side of the rear surface S3 to the side of the front surface S2. Here, as depicted in FIG. 3 and FIG. 4, it can be said that the trench section 29 partitions the semiconductor substrate 25 into multiple regions (hereinafter, also called the “element regions 30”). In addition, it can be said that the photoelectric converting sections 12 are formed in the respective element regions 30. FIG. 4 is a figure depicting a cross-sectional configuration of the solid-state imaging device 1 taken along a line B-B in FIG. 3. In addition, each element region 30 is in the shape of a cube having four surfaces (the side wall surfaces S4) on the side of the trench section 29.

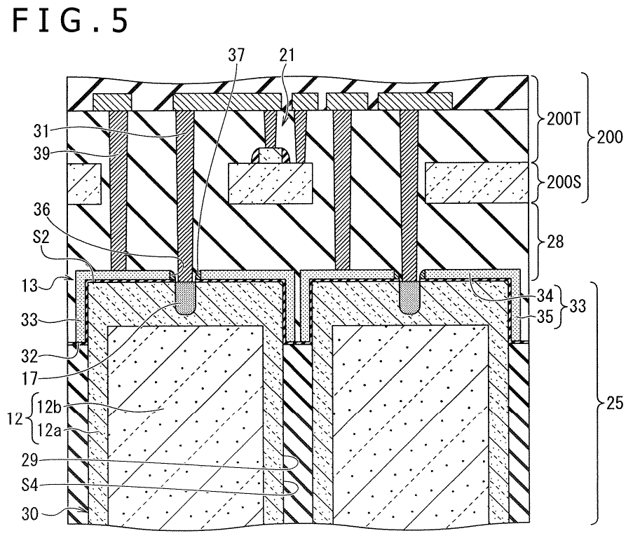

In addition, as depicted in FIG. 3, the FD 17 is formed in a region in the element region 30 on the side of the front surface S2 (on the side of the surface opposite to the light incidence surface) of the element region 30. When seen in the thickness direction of the semiconductor substrate 25, the FD 17 is formed at a central portion of the element region 30. In addition, the FD 17 is formed to reach a predetermined depth in the element region 30 from the front surface S2 of the element region 30. The FD 17 is thus exposed on the front surface S2 of the semiconductor substrate 25. In addition, the length to the depth position (predetermined depth position) where a leading end of the FD 17 is positioned is shorter than the thickness of the portion of the well region 12a which portion is positioned on the side of the front surface S2 of the element region 30. The periphery of the FD 17 is thus surrounded by the well region 12a and is separated from the second-conductivity-type region 12b. The FD 17 is configured using an n-type semiconductor region and retains charge transferred to the FD 17 from the photoelectric converting section 12 by a gate electrode 33. As depicted in FIG. 5, the FD 17 extends in the thickness direction of the first substrate 100, is electrically connected to a wire in the wiring layer 200T of the second substrate 200 via the contact 31 (an “electrode” in a broad sense) reaching the second substrate 200 from the first substrate 100, and is electrically connected to the pixel transistor 21 (e.g., the gate electrode of the amplification transistor 15 (see FIG. 2)). FIG. 3 illustrates a case where each of the FDs 17 is electrically connected to the corresponding contact 31 arranged to face the front surface S2 of the element region 30. The contact 31 is electrically connected to the region on the front surface S2 of the element region 30 where the FD 17 is formed (the region where the FD 17 is exposed; hereinbelow, also called a “first region 47”).

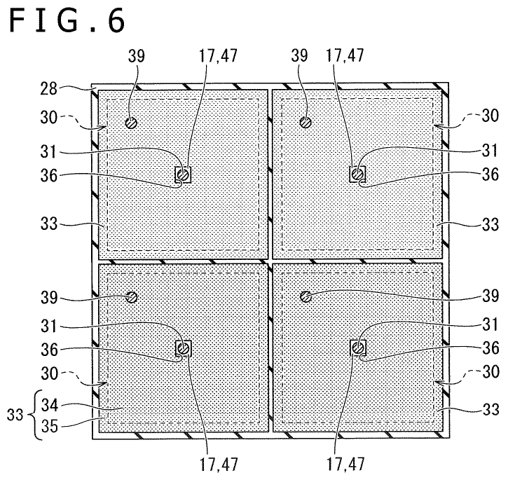

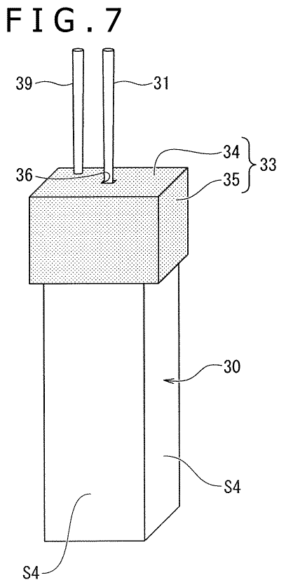

In addition, as depicted in FIG. 3, FIG. 6, and FIG. 7, the gate electrode 33 is formed at an end of the element region 30 on the side of the front surface S2 such that the gate electrode 33 wraps the end with a gate insulating film 32 being interposed therebetween. FIG. 6 is a figure depicting a planar configuration of gate electrodes taken along a line C-C in FIG. 3. In addition, FIG. 7 is a perspective view depicting configurations of an element region 30 and a gate electrode 33. Each gate electrode 33 has a tabular front electrode 34 covering the front surface S2 of the element region 30, and a tabular side electrode 35 covering each of the four side wall surfaces S4 (the surfaces on the side of the trench section 29) of the element region 30. By forming the front electrode 34, the area of the gate electrode 33 on the side of the second substrate 200 can be increased, a contact 39 for the gate electrode 33 can be prevented from being misaligned with the gate electrode 33, and also a double contact can be formed as the contact 39. The front electrode 34 is arranged to extend on the front surface S2 of the element region 30 excluding the region (first region 47) where the FD 17 is exposed, and has an opening (hereinafter, also called a “first opening 36”) through which the first region 47 is exposed. Note that, while FIG. 6 and FIG. 7 depict an example in which rectangular openings are used as an example of the first opening 36, this is not the sole example. Openings with various shapes such as a polygonal shape or a circular shape can be used. Electrical connection between the contact 31 and the FD 17 is established through the first opening 36. Here, it can be said that the gate electrode 33 continuously covers at least a part of the front surface S2 (the “first surface” in a broad sense) of the element region 30 excluding the region (the first region 47) which is on the front surface S2 and is the region where the FD 17 is formed, and at least parts of the surfaces (the “second surfaces” in a broad sense; the side wall surfaces S4) of the element region 30 on the side of the trench section 29. FIG. 3 illustrates a case where the gate electrode 33 continuously covers, at the end of the element region 30 on the side of the front surface S2, all of the region which is on the front surface S2 of the element region 30 and is a region where the FD 17 is not formed, and all the four side wall surfaces S4 of the element region 30. In addition, an inner circumferential surface of the first opening 36 of the front electrode 34 is covered with a sidewall 37. Note that illustration of the sidewalls 37 depicted in FIG. 3 is omitted in FIG. 6 and FIG. 7.

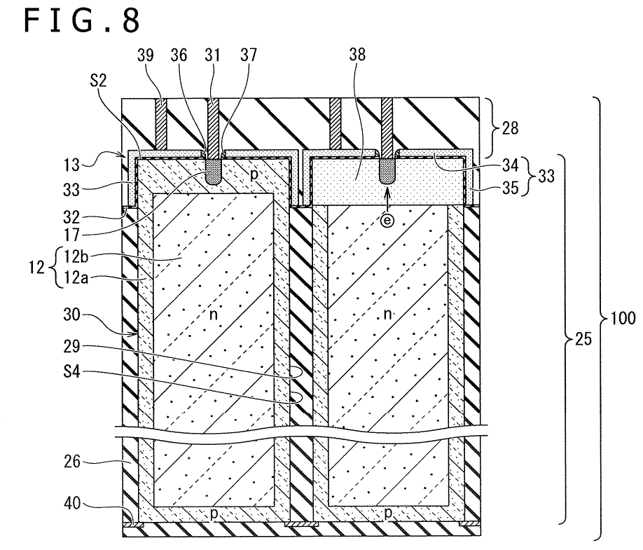

In addition, the side electrode 35 reaches a position deeper than the end of the FD 17 on the side of the rear surface S3, from the front surface S2 of the semiconductor substrate 25. In addition, the gate electrode 33 is electrically connected to a wire in the wiring layer 200T of the second substrate 200 via the contact 39 extending in the thickness direction of the first substrate 100. FIG. 3 illustrates a case where each of the gate electrodes 33 is electrically connected to the corresponding contact 39 arranged to face the front surface S2 of the element region 30. The transfer transistor 13 applies a predetermined voltage (e.g., Vdd) to the gate electrode 33 via the contact 39 at the time of charge transfer from the photoelectric converting section 12 to the FD 17. When the predetermined voltage is applied to the gate electrode 33, as depicted in FIG. 8, the transfer transistor 13 deepens the potential in the entire element region 30 (excluding the region of the FD 17) at the depth position where the gate electrode 33 is arranged. That is, a region 38 whose potential has been modulated is formed between the photoelectric converting section 12 and the FD 17. By forming the region 38 whose potential has been modulated, a transfer path that vertically transfers the charge stored in the photoelectric converting section 12 from the photoelectric converting section 12 to the FD 17 can be formed. As a result, the charge transfer path can be minimized, and the charge transfer efficiency can be enhanced.

Note that, in a case where the predetermined voltage is not applied to the gate electrode 33, the transfer transistor 13 does not form the region 38 whose potential has been modulated, and accordingly, the charge transfer path is not formed.

In addition, the insulating film 26 is embedded in an inner space of the trench section 29 where the side wall surfaces S4 are partially covered with the side electrodes 35. By embedding the insulating film 26, the gate electrodes 33 (the side electrodes 35) of adjacent element regions 30 are electrically insulated from each other. As the material of the insulating film 26, for example, silicon oxide (SiO₂) or silicon nitride (SiN) can be adopted.

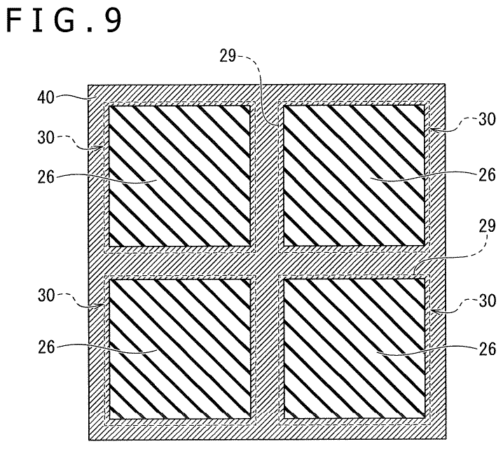

In addition, the well region 12a of the photoelectric converting section 12 is electrically connected to a supply source of predetermined potential (e.g., the ground) via a well electrode 40. The well electrode 40 is formed to face the rear surface S3 of the semiconductor substrate 25 and, as depicted in FIG. 9, is arranged along the trench section 29 such that the well electrode 40 closes an opening of the trench section 29 on the side of the rear surface S3. FIG. 9 is a figure depicting a planar configuration of the well electrode 40 taken along a line D-D in FIG. 3. The well electrode 40 is electrically connected to each of portions of the well regions 12a which portions are exposed on the side of the rear surface S3 of the element regions 30. The well electrode 40 is thus formed in such a grid that covers the opening of the trench section 29 on the side of the rear surface S3, and functions also as an inter-pixel light blocking section that hinders entrance of light to the opening. As the material of the well electrode 40, for example, metal such as aluminum (Al) or tungsten (W) can be adopted.

The insulating film 26 is arranged on the side of the rear surface S3 of the semiconductor substrate 25 and continuously covers the whole of the rear surface S3 and the inside of the trench section 29. The flattening film 27 is arranged on the side of a light incidence surface (hereinafter, also called a “rear surface S5”) of the insulating film 26 and continuously covers the rear surface S5 such that the rear surface S1 of the first substrate 100 becomes flat. As the material of the flattening film 27, for example, a material which is the same as that of the insulating film 26, such as silicon oxide (SiO₂) or silicon nitride (SiN), can be adopted.

The wiring layer 28 is arranged on the side of the front surface S2 of the semiconductor substrate 25. The wiring layer 28 has an interlayer dielectric film and wires (not depicted) stacked in multiple layers via the interlayer dielectric film.

As explained above, in the solid-state imaging device 1 according to the first embodiment, the FD 17 is formed to reach a predetermined depth in the element region 30 from the front surface S2 of the element region 30. In addition, the solid-state imaging device 1 has a configuration in which the transfer transistor 13 has the gate electrode 33 that continuously covers at least a part of the front surface S2 of the element region 30 excluding the region (the first region 47; the first surface) which is on the front surface S2 and is a region where the FD 17 is formed, and at least parts of the surfaces (the side wall surfaces S4; the second surfaces) of the element region 30 on the side of the trench section 29. As a result, the FD 17 is positioned in the element region 30, but the gate electrode 33 is positioned outside the element region 30 (in the trench section 29). Accordingly, for example, an extra space with a size corresponding to the gate electrode 33 can be created in the element region 30 as compared to a case where a structure in which both the FD 17 and the gate electrode 33 are positioned in the element region 30 is adopted. Therefore, for example, even in a case where miniaturization of pixel sizes advances and the size of the element region 30 is reduced, deterioration of the degree of freedom of the arrangement of the gate electrode 33 (a transfer gate) of the transfer transistor 13 and the FD 17 can be reduced. Accordingly, difficulty in arrangement of the transfer gate and the FD 17 caused by the reduction in pixel size can be reduced.

In addition, the solid-state imaging device 1 according to the first embodiment has a configuration in which the gate electrode 33 continuously covers all of the region which is on the front surface S2 of the element region 30 and is a region where the FD 17 is not formed, and all the four side wall surfaces S4 of the element region 30. Hence, the gate electrode 33 can perform modulation efficiently, and, as depicted in FIG. 8, the potential in the entire element region 30 can be deepened at the depth position where the gate electrode 33 (the side electrodes 35) is arranged. Accordingly, the charge stored in the photoelectric converting section 12 can be transferred vertically from the photoelectric converting section 12 to the FD 17 through the region where the potential has been deepened, the charge transfer path can be minimized, and the charge transfer efficiency can be enhanced. In addition, since the structure of the gate electrode 33 is simple, the gate electrode 33 can be formed with a reduced number of steps, and the gate electrode 33 can be formed easily.

### 1-4 Gate Electrode Production Method

Next, a method of producing the gate electrodes 33 is explained.

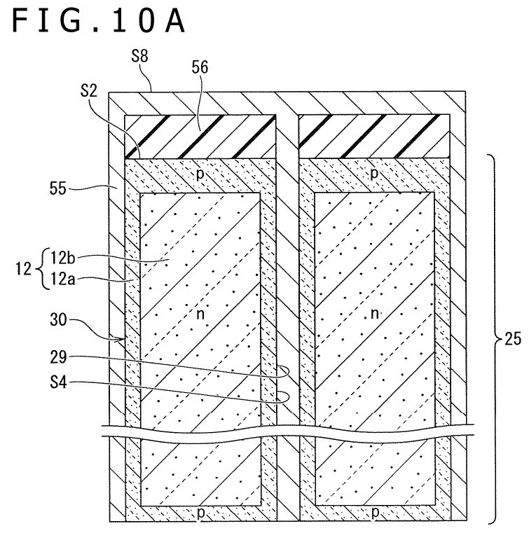

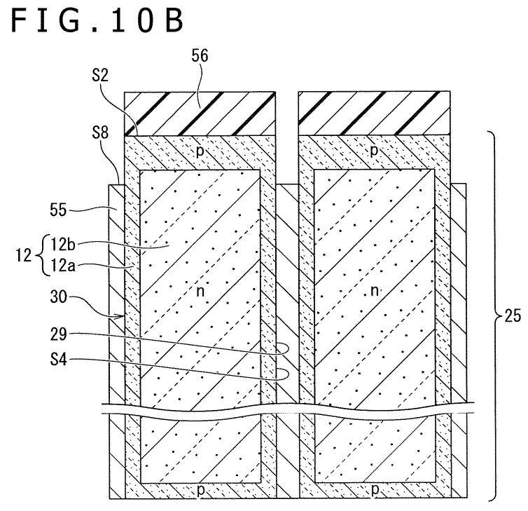

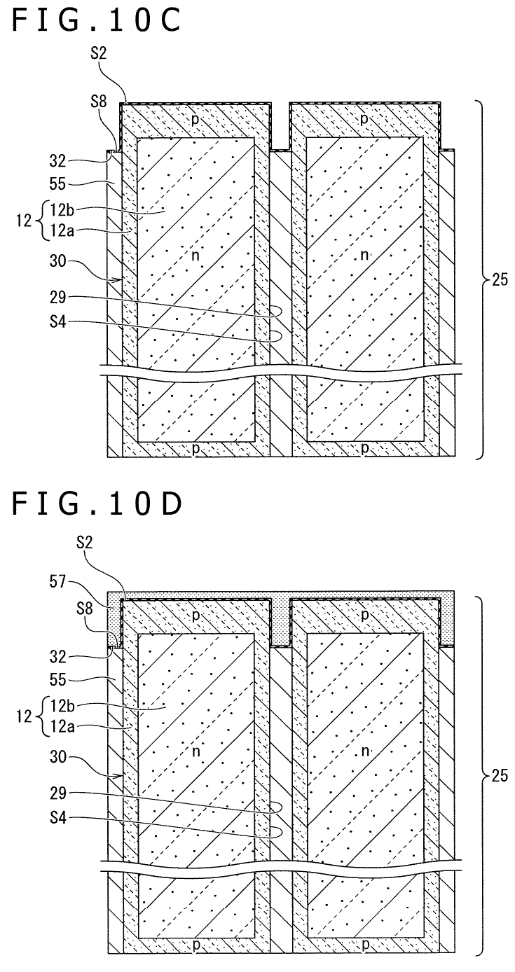

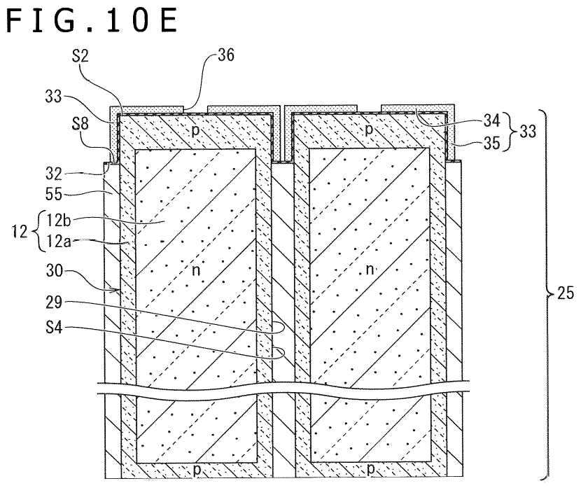

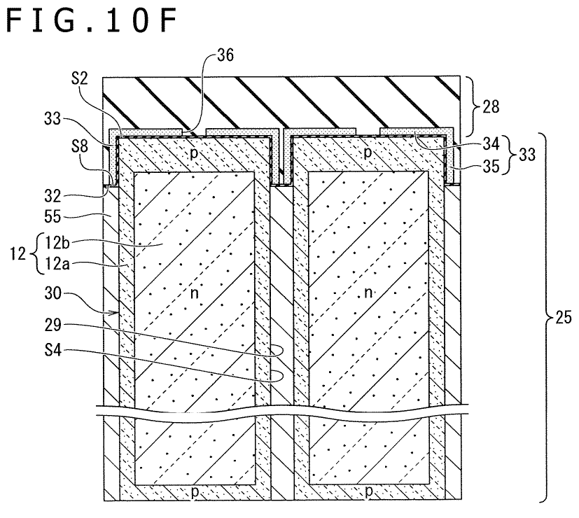

First, as depicted in FIG. 10A, after the trench section 29 and the element regions 30 are formed in the semiconductor substrate 25, the side of the front surface S2 (including etching masks 56) of the semiconductor substrate 25 is covered with polysilicon 55, and the polysilicon 55 is embedded in the trench section 29. Note that silicon oxide films (not depicted) may be formed between the element regions 30 and the polysilicon 55. The etching masks 56 are masks with a single layer structure or a multilayer structure that cover the front surfaces S2 of the respective element regions 30. Next, as depicted in FIG. 10B, the side of a front surface S8 of the polysilicon 55 is etched back, and ends of the etching masks 56 and the element regions 30 are exposed. Next, as depicted in FIG. 10C, the gate insulating film 32 is formed to continuously cover the front surfaces S2 of the element regions 30 and the front surface S8 of the polysilicon 55. Note that the silicon oxide films (not depicted) described above are removed in advance from the exposed ends of the element regions 30 before the formation of the gate insulating film 32.

Next, as depicted in FIG. 10D, irregularities on a front surface S9 of the gate insulating film 32 are covered with doped polysilicon 57 (the material of the gate electrodes 33). Next, as depicted in FIG. 10E, the doped polysilicon 57 is processed to form the gate electrodes 33. Next, as depicted in FIG. 10F, the wiring layer 28 is formed on the side of the front surface S2 of the semiconductor substrate 25, and the gate electrodes 33 are covered with the insulating film.

The gate electrodes 33 can be formed through steps like these.

Note that, as the process of manufacturing the solid-state imaging device 1, after the step depicted in FIG. 10F, the polysilicon 55 in the trench section 29 is removed, and the insulating film 26 is formed in the trench section 29. Consequently, the structure depicted in FIG. 3 in which the insulating film 26 is embedded in the inner space of the trench section 29 is formed.

### 1-5 Modification Examples

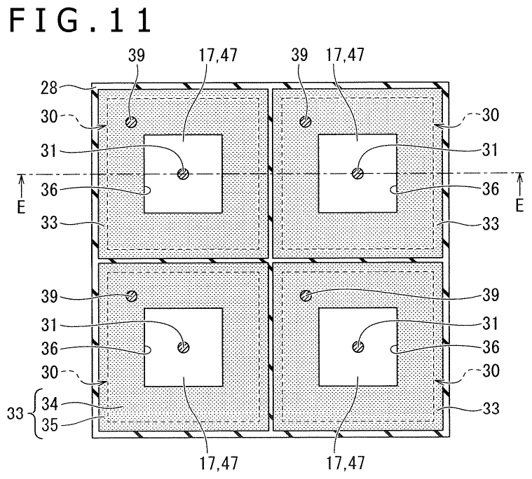

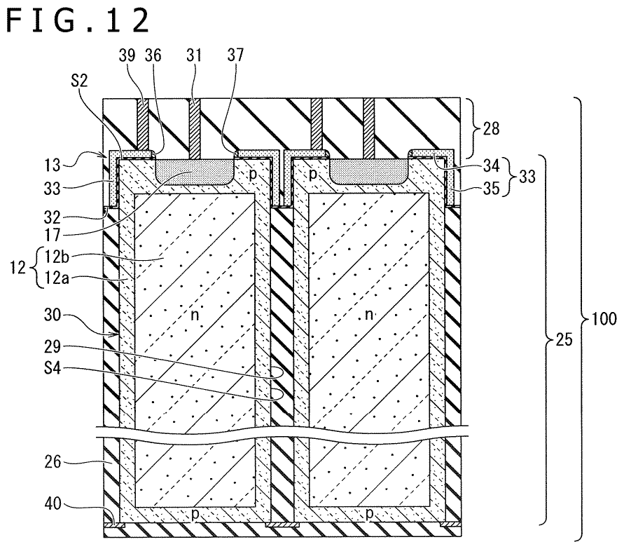

(1) Note that, while the first opening 36 of the gate electrode 33 is a small opening in the example depicted in the first embodiment, other configurations can also be adopted. For example, as depicted in FIG. 11 and FIG. 12, the first opening 36 may be made larger. By making the first opening 36 larger, the region of the FD 17 can be made larger. In addition, the size of the sidewalls 37 can be increased, offset between the gate electrode 33 and the FD 17 can be increased, and electrical fields generated between the gate electrode 33 and the FD 17 can be reduced. FIG. 11 is a figure depicting a planar configuration of the gate electrodes 33 taken along a position corresponding to the line C-C in FIG. 3. In addition, FIG. 12 is a figure depicting a cross-sectional configuration of the gate electrodes 33 taken along a line E-E in FIG. 11.

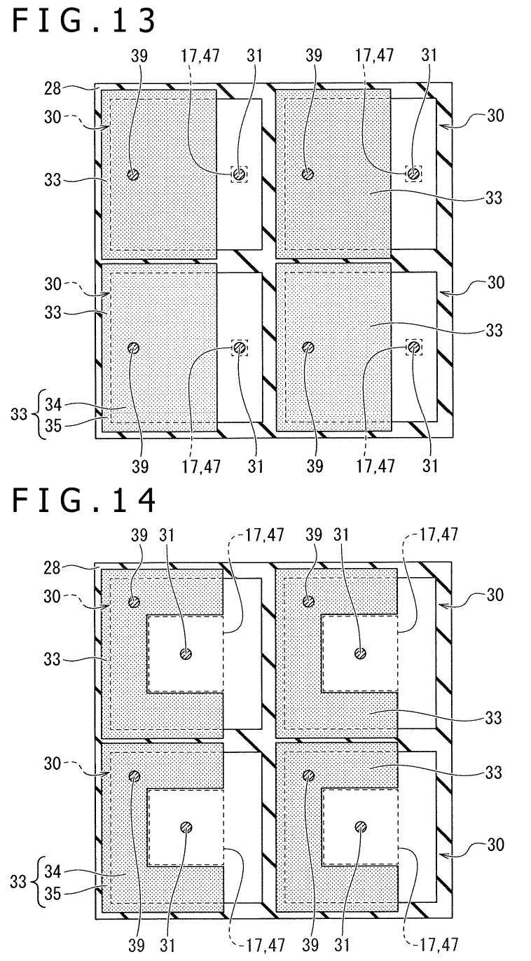

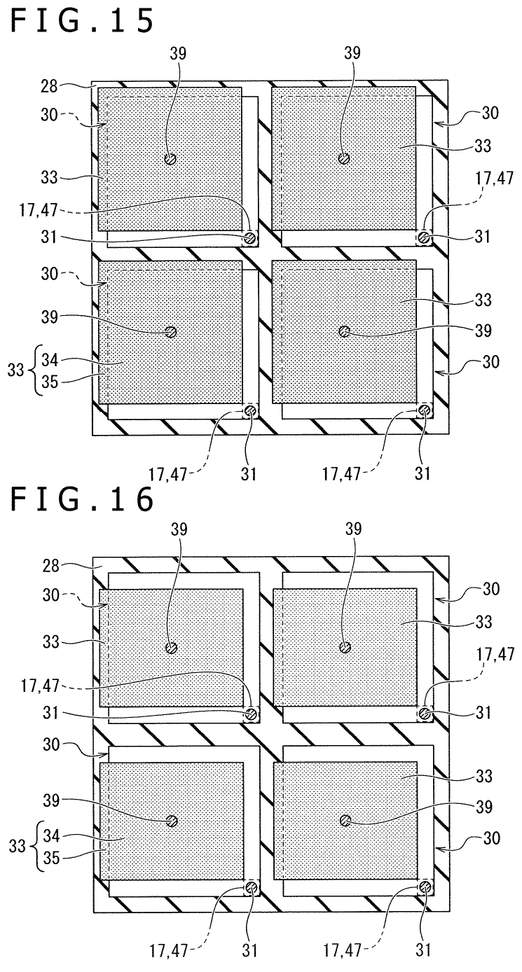

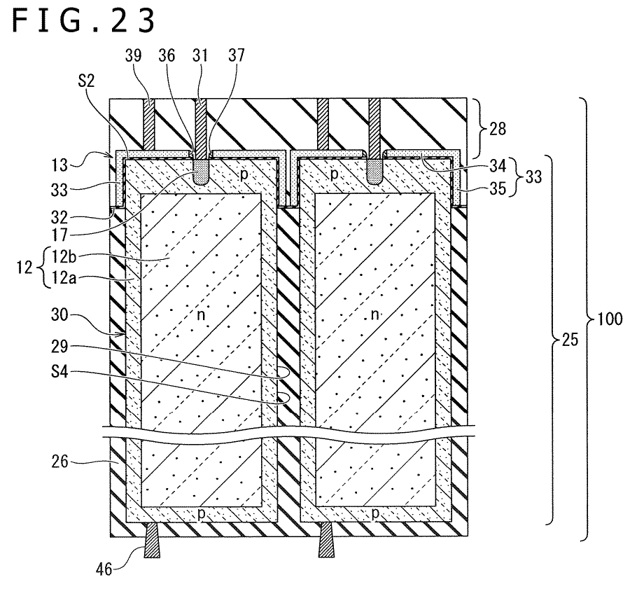

(2) In addition, while each gate electrode 33 (the side electrodes 35) covers all the four side wall surfaces S4 of the element region 30 in the example depicted in the first embodiment, other configurations can also be adopted. For example, as depicted in FIG. 13, FIG. 14, FIG. 15, and FIG. 16, each gate electrode 33 (the side electrode or side electrodes 35) covers only one, two, or three surfaces of the four side wall surfaces S4 of the element region 30, in other possible configurations. In the trench section 29 on the side of the surface (the side wall surface S4) not covered with the side electrode 35, an extra space with a size corresponding to the side electrode 35 can thus be created in the trench section 29. Accordingly, formation of the side electrodes 35 (the side electrodes 35 of other element regions 30) and embedding of the insulating film 26 in the trench section 29 can be performed easily. In addition, a region which is on the front surface S2 of the element region 30 but is not covered with the front electrode 34 can be made larger, and the region of the FD 17 can be made larger. In addition, for example, as will be mentioned later, the degree of freedom of layout of well contacts 46 (see FIG. 23 to FIG. 26 and the like) can be enhanced in a case where a configuration in which the well contacts 46 are connected to the well regions 12a from the side of the front surfaces S2 of the element regions 30 is adopted.

FIG. 13 and FIG. 14 illustrate cases where each gate electrode 33 (the side electrodes 35) covers three surfaces of the four side wall surfaces S4 of the element region 30. FIG. 15 illustrates a case where each gate electrode 33 (the side electrodes 35) covers two surfaces of the four side wall surfaces S4. FIG. 16 illustrates a case where each gate electrode 33 (the side electrode 35) covers one surface of the four side wall surfaces S4. Note that the configuration depicted in FIG. 14 is a modification example of the configuration depicted in FIG. 13 and is a configuration in which an opening is formed at a central portion of each front electrode 34 and the center of the front surface S2 of each element region 30 is not covered with the front electrode 34.

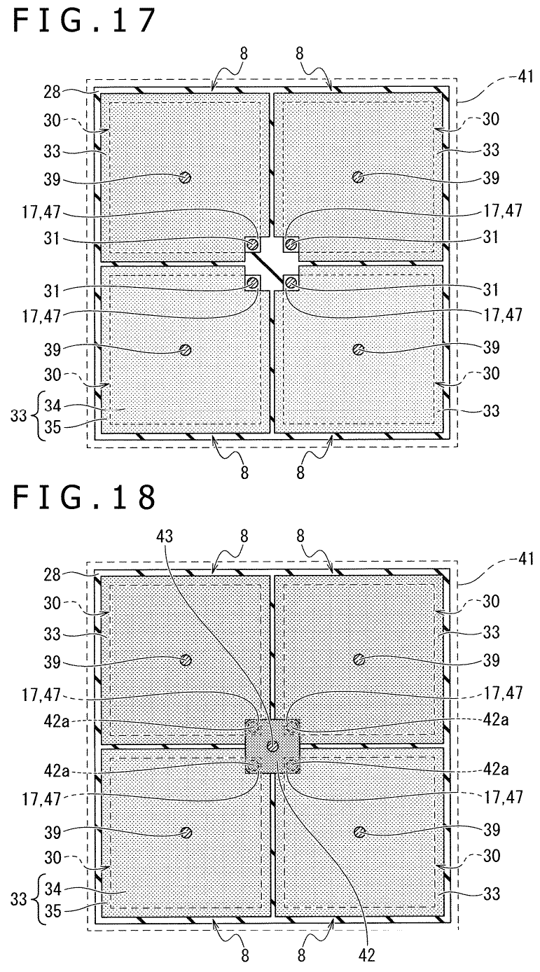

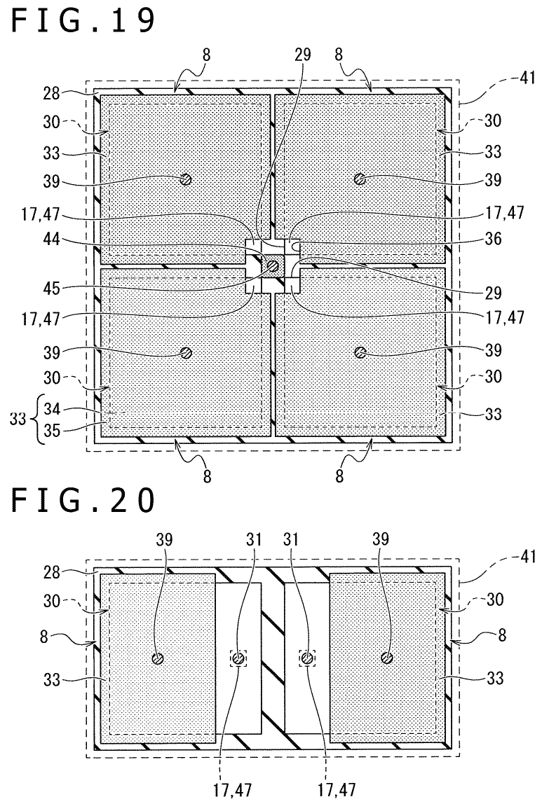

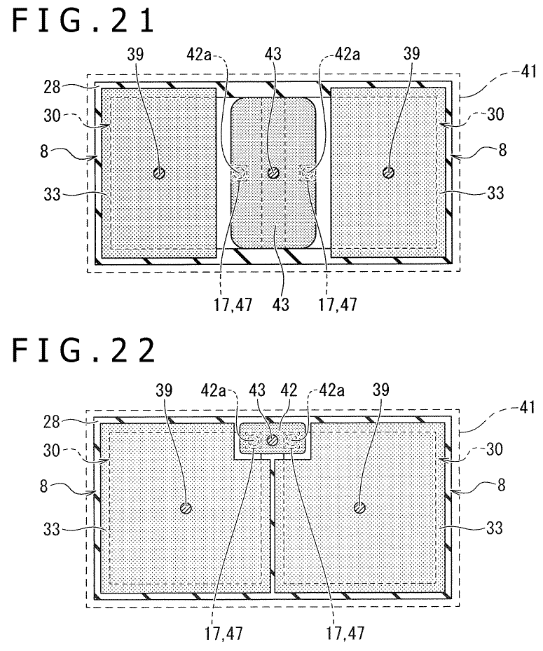

(3) In addition, while the FD 17 of each element region 30 (each pixel 8) is connected individually to the corresponding pixel transistor 21 in the example depicted in the first embodiment, other configurations can also be adopted. For example, as depicted in FIG. 17, FIG. 18, FIG. 19, FIG. 20, FIG. 21, and FIG. 22, the FDs 17 of two or more pixels 8 (element regions 30) have an FD sharing configuration in which the FDs 17 are electrically connected to each other, and the FDs 17 having the FD sharing configuration are electrically connected to one pixel transistor 21, in other possible configurations. FIG. 17, FIG. 18, and FIG. 19 depict cases where a pixel sharing unit 41 including 2×2, i.e., four, pixels 8 is regarded as a unit of FD 17 sharing, and illustrate cases where the FD 17 (the first region 47) of each pixel 8 is formed near a central portion of the pixel sharing unit 41. That is, when seen in the thickness direction of the semiconductor substrate 25, the FDs 17 (the first regions 47) are formed at corner portions of the pixels 8 (i.e., corner portions of the element regions 30). In addition, in these configurations, the FDs 17 are exposed at the side wall surfaces S4 of the corner portions of the element regions 30. Note that the configuration depicted in FIG. 17 is a configuration in which the contacts 31 for the FDs 17 are arranged near the central portion of the pixel sharing unit 41, and the four contacts 31 are electrically connected to each other through wires in the wiring layer 200T of the second substrate 200.

In addition, the configuration depicted in FIG. 18 is a configuration including, instead of the contacts 31 depicted in FIG. 17, a pad section 42 (a “first shared connection section” in a broad sense) and a through via 43 (a “first electrode” in a broad sense). The pad section 42 is formed in the wiring layer 28 of the first substrate 100 (at a position facing the front surfaces S2 of the element regions 30) and is arranged at the central portion of the pixel sharing unit 41 when seen in the thickness direction of the semiconductor substrate 25 (when seen on a planar view). The pad section 42 is arranged to be superimposed on each of two or more FDs 17 (the four FDs 17 in FIG. 18; the four first regions 47) in the pixel sharing unit 41, when seen on a planar view. As the material of the pad section 42, for example, doped polysilicon doped with impurities can be adopted. The pad section 42 is electrically connected to the two or more FDs 17 (the four FDs 17 in FIG. 18; the four first regions 47) via connection vias 42a. In addition, the through via 43 extends in the thickness direction of the semiconductor substrate 25, has one end electrically connected to the pad section 42, has another end electrically connected to a wire in the wiring layer 200T of the second substrate 200, and is electrically connected to the pixel transistor 21 (e.g., the gate electrode of the amplification transistor 15 (see FIG. 2)) via the wire in the wiring layer 200T. The through via 43 thus electrically connects the pad section 42 of the first substrate 100 and the pixel transistor 21 (see FIG. 3) that reads out the charge retained by the FD 17. Accordingly, according to the configuration depicted in FIG. 18, for example, the number of electrodes can be reduced, and the parasitic capacitance can be reduced, as compared to a method in which the FDs 17 are individually connected to the pixel transistors 21 by the contacts 31.

In addition, the configuration depicted in FIG. 19 is a configuration including, instead of the contacts 31 depicted in FIG. 17, a side contact 44 (a “first shared connection section” in a broad sense) and a through via 45 (a “first electrode” in a broad sense). The side contact 44 is formed in the trench section 29 of the first substrate 100 and is arranged at the central portion of the pixel sharing unit 41 when seen in the thickness direction of the semiconductor substrate 25 (when seen on a planar view). The side contact 44 is arranged among two or more FDs 17 (the four FDs 17 in FIG. 19) of the pixel sharing unit 41 (in the trench section 29 among the four FDs 17 in FIG. 19) such that the side contact 44 contacts each of the two or more FDs 17. As the material of the side contact 44, for example, doped polysilicon doped with impurities can be adopted. The side contact 44 is electrically connected to the two or more FDs 17 (the four FDs 17 in FIG. 19) exposed on the side wall surfaces S4 at the corner portions of the element regions 30. In addition, the through via 45 extends in the thickness direction of the semiconductor substrate 25, has one end electrically connected to the side contact 44, has another end electrically connected to a wire in the wiring layer 200T of the second substrate 200, and is electrically connected to the pixel transistor 21 (e.g., the gate electrode of the amplification transistor 15 (see FIG. 2) ) via the wire. The through via 45 thus electrically connects the side contact 44 of the first substrate 100 and the pixel transistor 21 (see FIG. 3) that reads out the charge retained by the FD 17. Accordingly, according to the configuration depicted in FIG. 19, for example, the number of electrodes can be reduced, and the parasitic capacitance can be reduced, as compared to a method in which the FDs 17 are connected to the pixel transistors 21 by separate contacts 31 (electrodes).

In addition, FIG. 20, FIG. 21, and FIG. 22 illustrate cases where a pixel sharing unit 41 including two pixels 8 is regarded as a unit of FD 17 sharing, and the FD 17 of each pixel 8 (element region 30) is formed near the central portion of the pixel sharing unit 41. As with the configuration depicted in FIG. 17, the configuration depicted in FIG. 20 is a configuration in which the contacts 31 of the FDs 17 are arranged near the central portion of the pixel sharing unit 41, and the two contacts 31 are electrically connected (not depicted) to each other in the wiring layer 200T of the second substrate 200. In addition, as with the configuration depicted in FIG. 18, the configurations depicted in FIG. 21 and FIG. 22 are configurations including a pad section 42 and a through via 43. FIG. 21 illustrates a case where the size of the pad section 42 is large, and FIG. 22 illustrates a case where the size of the pad section 42 is small.

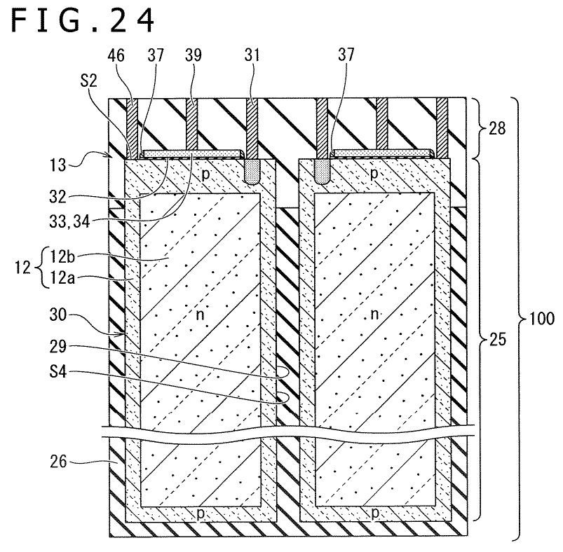

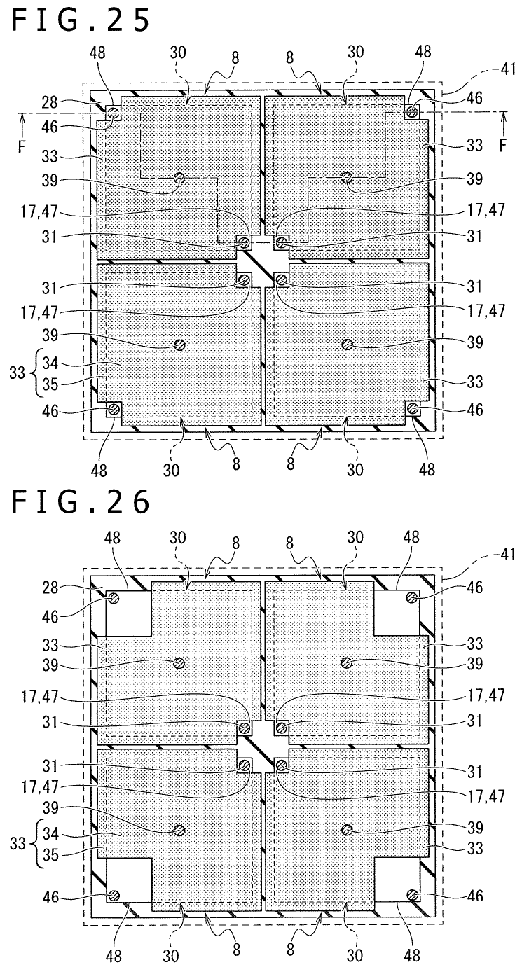

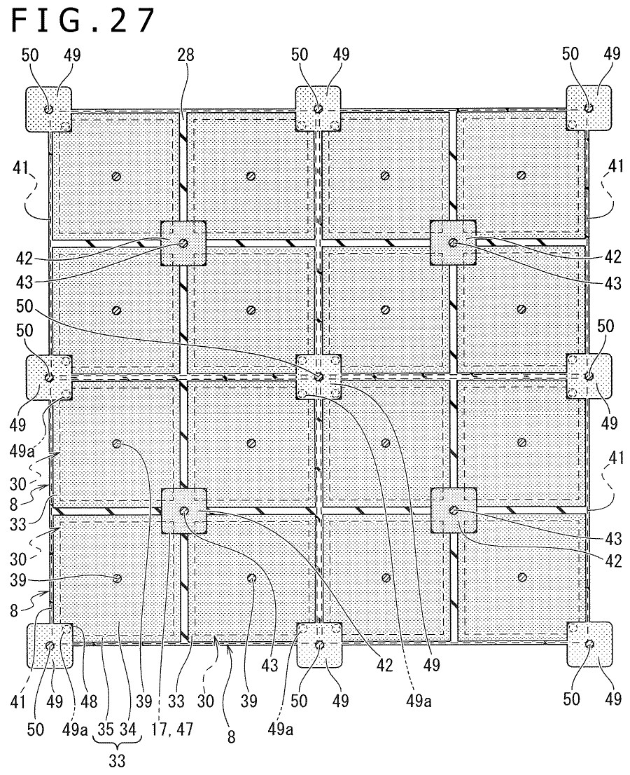

(4) In addition, while the well regions 12a are electrically connected to the supply source of predetermined potential (e.g., the ground) via the well electrode 40 arranged along the trench section 29 in the example depicted in the first embodiment, other configurations can also be adopted. For example, as depicted in FIG. 23, FIG. 24, and FIG. 25, the well regions 12a are electrically connected to the supply source of predetermined potential (the ground) via contacts (hereinafter, also called “well contacts 46”) each of which is formed for each element region 30 and extends in the thickness direction of the first substrate 100, in other possible configurations. Note that the configuration depicted in FIG. 23 is a configuration in which the well contacts 46 are formed to face the rear surfaces S3 of the element regions 30 and are electrically connected to portions of the well regions 12a which portions are exposed on the side of the rear surfaces S3. FIG. 26 illustrates a case where the large-sized FDs 17 depicted in FIG. 12 are included.

In addition, the configuration depicted in FIG. 24 and FIG. 25 is a configuration in which a well contact 46 is formed to face the front surface S2 of each element region 30 and is electrically connected to a portion of the well region 12a of each element region 30 which portion is exposed on the side of the front surface S2. That is, each of the well regions 12a is electrically connected to a separate contact (well contact 46). In the configuration depicted in FIG. 24 and FIG. 25, on the front surface S2 of each element region 30, the front electrode 34 of the gate electrode 33 is formed to exclude not only the region (the first region 47) where the FD 17 is formed but also a part (hereinafter, also called a “second region 48”) of the region where the well region 12a is formed. The well contact 46 is electrically connected to the second region 48. FIG. 24 is a figure depicting a cross-sectional configuration of the semiconductor substrate 25 taken along a line F-F in FIG. 25. Note that, because modulation at a portion near the well contact 46 is not necessary unlike at the portion near the FD 17, as depicted in FIG. 26, the area A₁ of the second region 48 may be made larger than the area A₂ of the first region 47 (A₁>A₂). By making A₁ larger than A₂, a highly precise contact formation technology is not required at the time of formation of the well contacts 46, so that the manufacturing cost can be reduced.

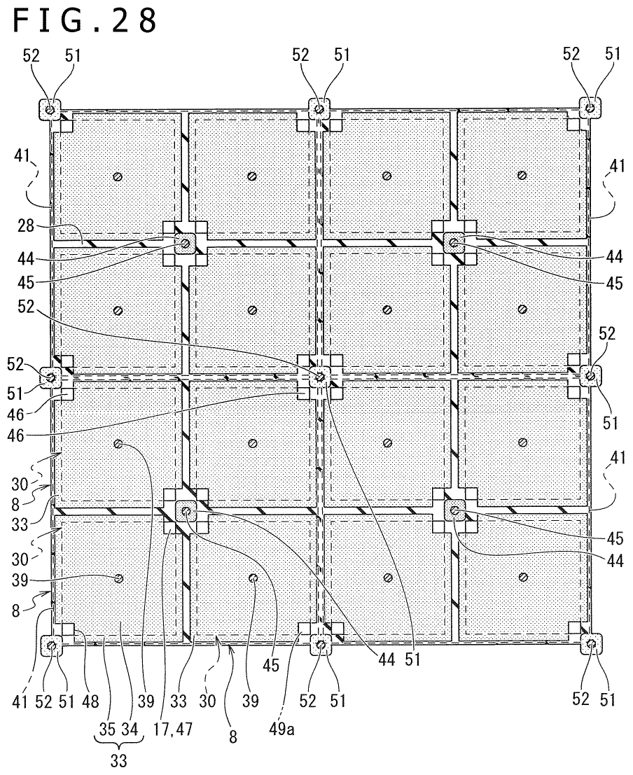

In addition, for example, as depicted in FIG. 27 and FIG. 28, the well regions 12a of two or more pixels 8 (element regions 30) are electrically connected to each other, in other possible configurations. The configuration depicted in FIG. 27 is a configuration including, at each of the four corner portions of a pixel sharing unit 41 including 2×2, i.e., four, pixels 8, a second region 48, a pad section 49 (a “second shared connection section” in a broad sense), and a through via 50 (a “second electrode” in a broad sense). Note that FIG. 27 illustrates a case where the pad sections 42 for the FDs 17 depicted in FIG. 18 are also included. Each pad section 49 is formed in the wiring layer 28 of the first substrate 100 (at a position facing the front surfaces S2 of the element regions 30) and is arranged at a central portion of 2×2, i.e., four, pixel sharing units 41 when seen in the thickness direction of the semiconductor substrate 25 (when seen on a planar view). The pad section 49 is arranged to be superimposed on each of two or more well regions 12a (four well regions 12a in FIG. 27; four second regions 48) in adjacent pixel sharing units 41, when seen on a planar view. As the material of the pad section 49, for example, doped polysilicon doped with impurities can be adopted. The pad section 49 is electrically connected to the two or more well regions 12a (the four well regions 12a in FIG. 27; the four second regions 48) via connection vias 48a. In addition, the through via 43 extends in the thickness direction of the semiconductor substrate 25, has one end electrically connected to the pad section 49, has another end electrically connected to a wire in the wiring layer 200T of the second substrate 200, and is electrically connected, via the wire, to a supply source of predetermined potential (the ground) that the second substrate 200 has. The through via 43 thus electrically connects the pad section 49 of the first substrate 100 and the supply source of the predetermined potential that the second substrate 200 has. Accordingly, according to the configuration depicted in FIG. 27, for example, the number of electrodes can be reduced, and the parasitic capacitance can be reduced, as compared to a method in which the well regions 12a are connected to a supply source of predetermined potential by separate contacts.

In addition, the configuration depicted in FIG. 28 is a configuration including, at each of the four corner portions of a pixel sharing unit 41 including 2×2, i.e., four, pixels 8, a side contact 51 (a “second shared connection section” in a broad sense) and a through via 52 (a “second electrode” in a broad sense). Note that FIG. 28 illustrates a case where the side contacts 44 for the FDs 17 depicted in FIG. 19 are also included. The side contact 51 is formed in the trench section 29 of the first substrate 100 and is arranged at a central portion of 2×2, i.e., four, pixel sharing units 41 when seen in the thickness direction of the semiconductor substrate 25 (when seen on a planar view). The side contact 51 is arranged among two or more well regions 12a (four well regions 12a in FIG. 28) in adjacent four pixel sharing units 41 (in the trench section 29 among the four well regions 12a in FIG. 28) such that the side contact 51 contacts each of the two or more well regions 12a. As the material of the side contact 51, for example, doped polysilicon doped with impurities can be adopted. The side contact 51 is electrically connected to the two or more well regions 12a (the four well regions 12a in FIG. 28) exposed on the side wall surfaces S4 at the corner portions of the element regions 30. In addition, the through via 52 extends in the thickness direction of the semiconductor substrate 25, has one end electrically connected to the side contact 51, has another end electrically connected to a wire in the wiring layer 200T of the second substrate 200, and is electrically connected, via the wire, to a supply source of predetermined potential (the ground) that the second substrate 200 has. The through via 52 thus electrically connects the side contact 51 of the first substrate 100 and the supply source (the ground) of the predetermined potential that the second substrate 200 has. Accordingly, according to the configuration depicted in FIG. 28, for example, the number of electrodes can be reduced, and the parasitic capacitance can be reduced, as compared to a method in which the well regions 12a are connected to a supply source of predetermined potential by separate contacts (electrodes).

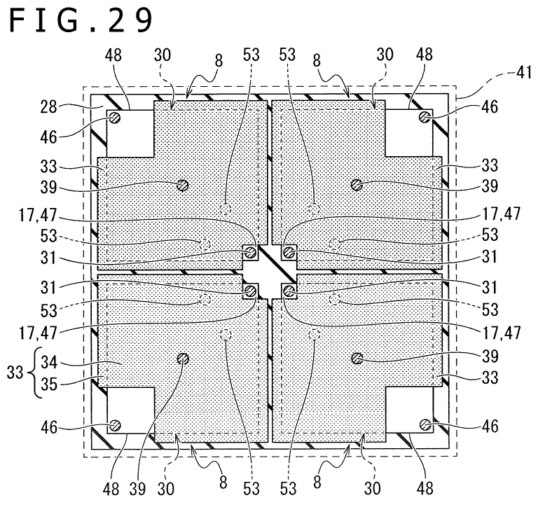

(5) In addition, while each gate electrode 33 includes the front electrode 34 and the side electrodes 35 in the example depicted in the first embodiment, other configurations can also be adopted. For example, as depicted in FIG. 29, in addition to the front electrode 34 and the side electrodes 35, each gate electrode 33 has vertical electrode sections 53 reaching a predetermined depth in the element region 30 from the front surface S2 of the element region 30, in other possible configurations. The vertical electrode sections 53 are arranged at portions of the front electrode 34 closer to the FD 17 (near the first region 47). FIG. 29 illustrates a case where two columnar vertical electrode sections 53 are formed in each gate electrode 33. Note that the shape and number of vertical electrode sections 53 are not limited to these. The vertical electrode sections 53 can boost the modulation near the FD 17.

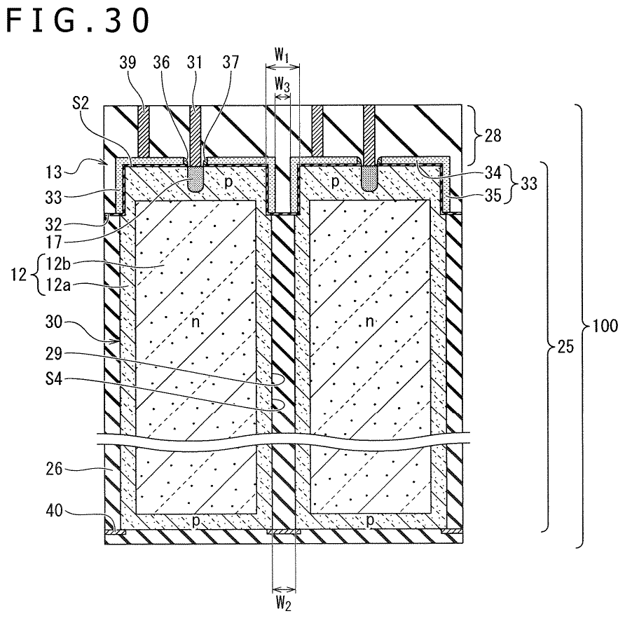

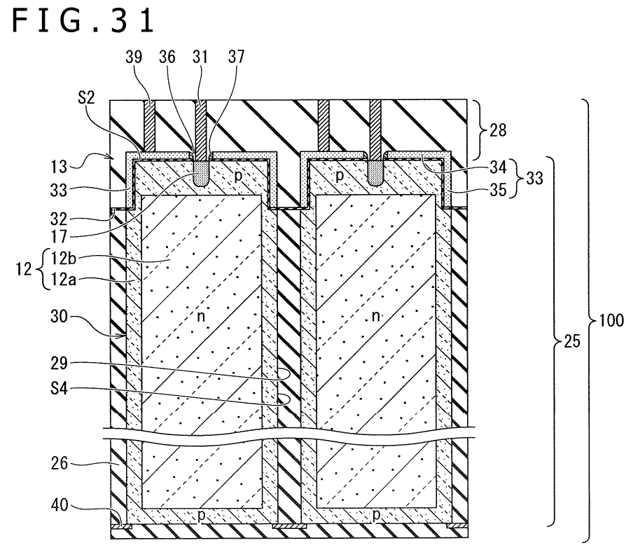

(6) In addition, while the groove width of the trench section 29 is constant in the example depicted in the first embodiment, other configurations can also be adopted. For example, as depicted in FIG. 30 and FIG. 31, the groove width W₁ of portions of the side wall surfaces S4 of the trench section 29 which portions are covered with the gate electrodes 33 (the side electrodes 35) is made larger than the groove width W₂ of portions of the side wall surfaces S4 of the trench section 29 which portions are not covered with the gate electrodes 33 (the side electrodes 35) (W₁>W₂), in other possible configurations. An extra space with a size corresponding to the increase (W₁−W₂) in the groove width can thus be created at the portions in the trench section 29 which portions are covered with the side electrodes 35. Accordingly, formation of the side electrodes 35 and embedding of the insulating film 26 in the trench section 29 can be performed easily. FIG. 30 illustrates a case where the width W₃ between the side electrodes 35 is smaller than the groove width W₂. In addition, FIG. 31 illustrates a case where the groove width W₂ and the width W₃ are the same.

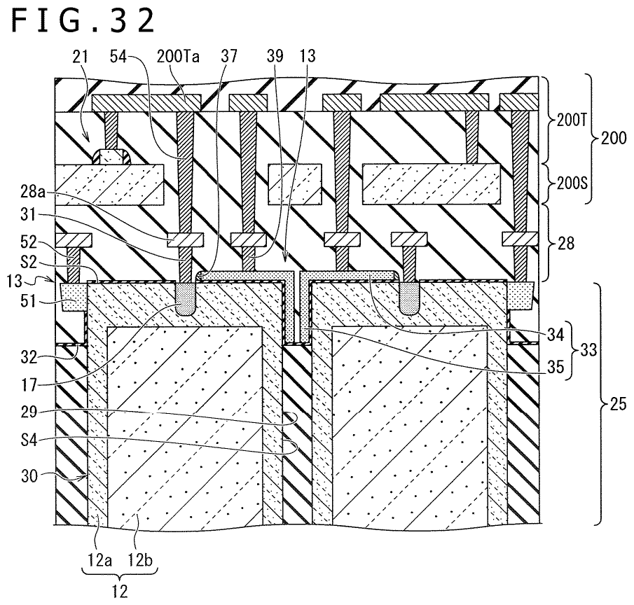

(7) In addition, while the FDs 17 in the first substrate 100 and the pixel transistors 21 in the second substrate 200 are electrically connected to each other by the contacts 31 in the example depicted in the first embodiment, other configurations can also be adopted. For example, as depicted in FIG. 32, the FDs 17 in the first substrate 100 and the pixel transistors 21 in the second substrate 200 are electrically connected to each other by wires 28a in the wiring layer 28 of the first substrate 100 and electrodes (hereinafter, also called “through vias 54”) reaching the second substrate 200 from the wiring layer 28, in other possible configurations. Note that FIG. 32 illustrates a case where the side contacts 51 depicted in FIG. 28 are also included. Each wire 28a in the wiring layer 28 of the first substrate 100 is electrically connected to the corresponding contact 31 extending from the front surface S2 of the FD 17. In addition, the through via 54 extends in the thickness direction of the semiconductor substrate 25, has one end electrically connected to the wire 28a in the wiring layer 28, and has another end electrically connected to a wire 200Ta in the wiring layer 200T of the second substrate 200. In addition, the other end is electrically connected to the wire 200Ta in the wiring layer 200T of the second substrate 200 and is electrically connected to the pixel transistor 21 (e.g., the gate electrode of the amplification transistor 15 (see FIG. 2)) via the wire 200Ta. The wire 28a in the wiring layer 28, the through via 54, and the wire 200Ta in the wiring layer 200T thus electrically connect the FD 17 and the pixel transistor 21 to each other. As the materials of the wires 28a and 200Ta, for example, doped polysilicon, tungsten (W), or copper (Cu) can be adopted.

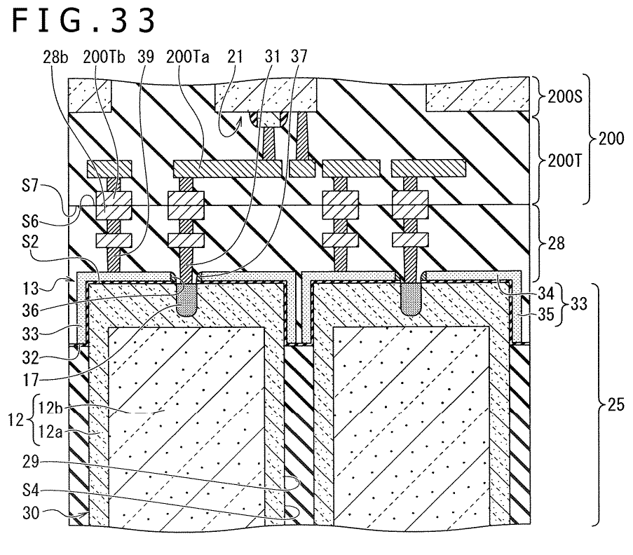

In addition, for example, as depicted in FIG. 33, the FDs 17 and the pixel transistors 21 are electrically connected to each other via multiple first electrode pads 28b arranged on a surface (hereinafter, also called a “front surface S6”) of the first substrate 100 on the side of the second substrate 200, and multiple second electrode pads 200Tb that are arranged on a surface (hereinafter, also called a “rear surface S7”) of the second substrate 200 on the side of the first substrate 100 and are joined with the respective first electrode pads 28b, in other possible configurations. That is, the configuration depicted in FIG. 33 is a configuration in which Cu—Cu connection is used as connection between the first substrate 100 and the second substrate 200, as with connection between the second substrate 200 and the third substrate 300 depicted in FIG. 3. Each first electrode pad 28b has one end electrically connected to the corresponding contact 31 extending from the front surface S2 of the FD 17 and has another end exposed on the front surface S6 of the wiring layer 200T. In addition, each second electrode pad 200Tb has one end exposed on the rear surface S7 of the wiring layer 200T and electrically connected to the corresponding first electrode pad 28b, and has another end electrically connected to the corresponding wire 200Ta in the wiring layer 200T of the second substrate 200 and electrically connected to the pixel transistor 21 (e.g., the gate electrode of the amplification transistor 15 (see FIG. 2)) via the wire 200Ta. The first electrode pad 28b in the first substrate 100 and the second electrode pad 200Tb in the second substrate 200 thus electrically connect the FD 17 and the pixel transistor 21 to each other. As the material of the first electrode pad 28b and the material of the second electrode pad 200Tb, for example, copper (Cu) or aluminum (Al) can be adopted.

(8) In addition, the present technology can be applied not only to the solid-state imaging device 1 as an image sensor mentioned above, but also to light detecting devices in general including distance measurement sensors that measure distances and are also called ToF (Time of Flight) sensors, and the like. The distance measurement sensors are sensors that emit irradiation light toward an object, detect reflection light generated by reflection of the irradiation light on a surface of the object, and compute the distance to the object on the basis of time of flight from the emission of the irradiation light until reception of the reflection light. As a light-receiving pixel structure of the distance measurement sensors, the structure of pixels 8 mentioned above can be adopted.

### 2. Second Embodiment

The technology according to the present disclosure (the present technology) may be applied to various electronic apparatuses.

FIG. 34 is a figure depicting a schematic configuration example of an imaging apparatus (a video camera, a digital still camera, etc.) as an electronic apparatus to which the present technology is applied.

As depicted in FIG. 34, an imaging apparatus 1000 includes the lens group 1001, the solid-state imaging device 1002 (the solid-state imaging device 1 according to the first embodiment), a DSP (Digital Signal Processor) circuit 1003, a frame memory 1004, a monitor 1005, and a memory 1006. The DSP circuit 1003, the frame memory 1004, the monitor 1005, and the memory 1006 are interconnected via a bus line 1007.

The lens group 1001 guides incident light (image light) from a subject to the solid-state imaging device 1002 and causes an image of the incident light to be formed on a light reception surface (pixel region) of the solid-state imaging device 1002.

The solid-state imaging device 1002 includes the CMOS image sensor of the first embodiment mentioned above. The solid-state imaging device 1002 converts light amounts of the incident light whose image has been formed on the light reception surface by the lens group 1001, into electric signals pixel by pixel, and supplies the electric signals to the DSP circuit 1003 as pixel signals.

The DSP circuit 1003 performs predetermined image processing on the pixel signals supplied from the solid-state imaging device 1002. Further, the DSP circuit 1003 supplies, to the frame memory 1004, image signals obtained after the image processing, frame by frame, and causes the frame memory 1004 to temporarily store the image signals.

For example, the monitor 1005 includes a panel-type display device such as a liquid crystal panel or an organic EL (Electro Luminescence) panel. The monitor 1005 displays an image (video) of the subject on the basis of frame-by-frame pixel signals temporarily stored on the frame memory 1004.

The memory 1006 includes a DVD, a flash memory, and the like. The memory 1006 reads out and records frame-by-frame pixel signals temporarily stored on the frame memory 1004.

Note that electronic apparatuses to which the solid-state imaging device 1 can be applied are not limited to the imaging apparatus 1000, and the solid-state imaging device 1 can be applied also to other electronic apparatuses. In addition, while the solid-state imaging device 1 according to the first embodiment is used as the solid-state imaging device 1002 in the configuration mentioned above, other configurations can also be adopted. For example, other light detecting devices to which the present technology is applied, such as the solid-state imaging device 1 according to the modification examples, are used, in other possible configurations.

Note that the present technology can also adopt configurations like the ones below.

(1)

A light detecting device including:
a semiconductor substrate;
a trench section that partitions the semiconductor substrate into multiple element regions;
a photoelectric converting section that is formed in each element region and generates and stores charge according to a light reception amount;
a charge retaining section that is formed in each element region and retains charge generated in the photoelectric converting section; and
a transfer transistor that transfers, to the charge retaining section, charge stored in the photoelectric converting section, in which
the charge retaining section is formed to reach a predetermined depth in the element region from a first surface of the element region that is a surface opposite to a light incidence surface of the element region, and
the transfer transistor has a gate electrode that continuously covers at least a part of the first surface of the element region excluding a first region that is on the first surface and is a region where the charge retaining section is formed, and at least a part of a second surface that is a surface of the element region on a side of the trench section.
   (2)

The light detecting device according to (1) above, in which the charge retaining section is formed at a central portion of the element region when seen in a thickness direction of the semiconductor substrate.

(3)

The light detecting device according to (1) above, in which the charge retaining section is formed at a corner portion of the element region when seen in a thickness direction of the semiconductor substrate.

(4)

The light detecting device according to (3) above, in which
the element region is a cube having four second surfaces, and
the gate electrode covers three second surfaces of the four second surfaces of the element region.
   (5)

The light detecting device according to (3) above, in which
the element region is a cube having four second surfaces, and
the gate electrode covers two second surfaces of the four second surfaces of the element region.
   (6)

The light detecting device according to (3) above, in which
the element region is a cube having four second surfaces, and
the gate electrode covers one second surface of the four second surfaces of the element region.
   (7)

The light detecting device according to any of (1) through (6) above, in which each charge retaining section and each gate electrode are electrically connected to a contact arranged to face the first surface of the corresponding element region.

(8)

The light detecting device according to any of (3) through (7) above, including:
a first shared connection section electrically connected to the charge retaining sections of two or more element regions; and
a first electrode electrically connected to the first shared connection section, in which
the first shared connection section is arranged to be superimposed on each of the two or more charge retaining sections at positions facing the first surfaces of the element regions, or is arranged between the two or more charge retaining sections.
   (9)

The light detecting device according to any of (1) through (8) above, in which
the photoelectric converting section has a first-conductivity-type well region and a second-conductivity-type region that is of a second conductivity type and forms a pn junction with the well region,
the well region is exposed on a side of the light incidence surface of the element region,
a well electrode that is formed to face the light incidence surfaces of the element regions and is arranged along the trench section such that the well electrode closes an opening of the trench section on a side of the light incidence surfaces is provided, and
the well electrode is electrically connected to a portion of the well region which portion is exposed on the side of the light incidence surface of each element region.
   (10)

The light detecting device according to any of (1) through (8) above, in which
the photoelectric converting section has a first-conductivity-type well region and a second-conductivity-type region that is of a second conductivity type and forms a pn junction with the well region,
the well region is exposed on a side of the light incidence surface of the element region, and
a well contact that is formed to face the light incidence surface of the element region and is electrically connected to a portion of the well region which portion is exposed on the side of the light incidence surface of the element region is provided.
   (11)

The light detecting device according to any of (1) through (8) above, in which
the photoelectric converting section has a first-conductivity-type well region and a second-conductivity-type region that is of a second conductivity type and forms a pn junction with the well region,
the well region is exposed on a side of the first surface of the element region, and,
on the first surface of the element region, the gate electrode is formed to exclude not only the first region but also a second region that is a part of a region where the well region is formed.
   (12)

The light detecting device according to (11) above, in which each well region is electrically connected to a well contact arranged to face the first surface of the corresponding element region.

(13)

The light detecting device according to (11) above, including:
a second shared connection section electrically connected to the well regions of two or more element regions; and
a second electrode electrically connected to the second shared connection section, in which
the second shared connection section is arranged to be superimposed on each of the two or more well regions at positions facing the first surfaces of the element regions, or is arranged between the two or more well regions.
   (14)

The light detecting device according to any of (11) through (13) above, in which an area of the second region is greater than an area of the first region.

(15)

The light detecting device according to any of (1) through (14) above, in which the gate electrode has a vertical electrode section reaching a predetermined depth in the element region from the first surface of the element region.

(16)

The light detecting device according to any of (1) through (15) above, in which the gate electrode reaches, from the first surface of the semiconductor substrate, a position located deeper than an end of the charge retaining section on a side of the second surface.

(17)

The light detecting device according to any of (1) through (15) above, in which a groove width of a portion of side wall surfaces of the trench section which portion is covered with the gate electrode is larger than a groove width of a portion of the side wall surfaces of the trench section which portion is not covered with the gate electrode.

(18)

The light detecting device according to any of (1) through (17) above, including:
a first substrate having the semiconductor substrate; and
a second substrate stacked on the first substrate, the second substrate having pixel transistors that read out charge retained in the charge retaining sections of the semiconductor substrate, in which
the charge retaining sections and the pixel transistors are electrically connected to each other via electrodes that extend in a thickness direction of the first substrate and reach the second substrate from the first substrate.
   (19)

The light detecting device according to any of (1) through (17) above, including:
a first substrate having the semiconductor substrate; and
a second substrate stacked on the first substrate, the second substrate having pixel transistors that read out charge retained in the charge retaining sections of the semiconductor substrate, in which
the first substrate has a wiring layer arranged on a surface of the semiconductor substrate on a side of the second substrate, and
the charge retaining sections and the pixel transistors are electrically connected to each other via wires in the wiring layer of the first substrate and electrodes that extend in a thickness direction of the first substrate and reach the second substrate from the wiring layer.
   (20)

The light detecting device according to any of (1) through (17) above, including:
a first substrate having the semiconductor substrate; and
a second substrate stacked on the first substrate, the second substrate having pixel transistors that read out charge retained in the charge retaining sections of the semiconductor substrate, in which
the charge retaining sections and the pixel transistors are electrically connected to each other via multiple first electrode pads arranged on a surface of the first substrate on a side of the second substrate and multiple second electrode pads that are arranged on a surface of the second substrate on a side of the first substrate and are joined with the respective first electrode pads.
   (21)

The light detecting device according to any of (1) through (20) above, in which, when a predetermined voltage is applied, the gate electrode deepens potential in the entire element region excluding a region where the charge retaining section is formed, at a depth position where the gate electrode is arranged.

(22)

An electronic apparatus including:
a light detecting device including
   a semiconductor substrate,
   a trench section that partitions the semiconductor substrate into multiple element regions,
   a photoelectric converting section that is formed in each element region and generates and stores charge according to a light reception amount,
   a charge retaining section that is formed in each element region and retains charge generated in the photoelectric converting section, and
   a transfer transistor that transfers, to the charge retaining section, charge stored in the photoelectric converting section,
   the charge retaining section being formed to reach a predetermined depth in the element region from a first surface of the element region that is a surface opposite to a light incidence surface of the element region, and
   the transfer transistor having a gate electrode that continuously covers at least a part of the first surface of the element region excluding a first region that is on the first surface and is a region where the charge retaining section is formed, and at least a part of a second surface that is a surface of the element region on a side of the trench section.

### REFERENCE SIGNS LIST

1: Solid-state imaging device
2: Pixel region
3: Vertical drive circuit
4: Column signal processing circuit
5: Horizontal drive circuit
6: Output circuit
7: Control circuit
8: Pixel
9: Pixel driving wire
10: Vertical signal line
11: Horizontal signal line
12: Photoelectric converting section
12a: Well region
12b: Second-conductivity-type region
13: Transfer transistor
14: Reset transistor
15: Amplification transistor
16: Selection transistor
17: FD
18: Transfer line
19: Reset line
20: Selection line
21: Pixel transistor
22: Logic circuit
23: Color filter
24: Microlens
25: Semiconductor substrate
26: Insulating film
27: Flattening film
28: Wiring layer
28a: Wire
28b: First electrode pad
29: Trench section
30: Element region
31: Contact
32: Gate insulating film
33: Gate electrode
34: Front electrode
35: Side electrode
36: First opening
37: Sidewall
38: Region whose potential is modulated
39: Contact
40: Well electrode
41: Pixel sharing unit
42: Pad section
42a: Connection via
43: Through via
44: Side contact
45: Through via
46: Well contact
47: First region
48: Second region
48a: Connection via
49: Pad section
50: Through via
51: Side contact
52: Through via
53: Vertical electrode section
54: Through via
55: Polysilicon
56: Etching mask
57: Doped polysilicon
100: First substrate
200: Second substrate
200S: Semiconductor layer
200T: Wiring layer
200Ta: Wire
200Tb: Second electrode pad
201: Electrode pad
300: Third substrate
300S: Semiconductor layer
300T: Wiring layer
301: Electrode pad
1000: Imaging apparatus
1001: Lens group
1002: Solid-state imaging device
1003: DSP circuit
1004: Frame memory
1005: Monitor
1006: Memory
1007: Bus line

1. A light detecting device comprising:
a semiconductor substrate;
a trench section that partitions the semiconductor substrate into multiple element regions;
a photoelectric converting section that is formed in each element region and generates and stores charge according to a light reception amount;
a charge retaining section that is formed in each element region and retains charge generated in the photoelectric converting section; and
a transfer transistor that transfers, to the charge retaining section, charge stored in the photoelectric converting section, wherein
the charge retaining section is formed to reach a predetermined depth in the element region from a first surface of the element region that is a surface opposite to a light incidence surface of the element region, and
the transfer transistor has a gate electrode that continuously covers at least a part of the first surface of the element region excluding a first region that is on the first surface and is a region where the charge retaining section is formed, and at least a part of a second surface that is a surface of the element region on a side of the trench section.

2. The light detecting device according to claim 1, wherein the charge retaining section is formed at a central portion of the element region when seen in a thickness direction of the semiconductor substrate.

3. The light detecting device according to claim 1, wherein the charge retaining section is formed at a corner portion of the element region when seen in a thickness direction of the semiconductor substrate.

4. The light detecting device according to claim 3, wherein
the element region is a cube having four second surfaces, and
the gate electrode covers three second surfaces of the four second surfaces of the element region.

5. The light detecting device according to claim 3, wherein
the element region is a cube having four second surfaces, and
the gate electrode covers two second surfaces of the four second surfaces of the element region.

6. The light detecting device according to claim 3, wherein
the element region is a cube having four second surfaces, and
the gate electrode covers one second surface of the four second surfaces of the element region.

7. The light detecting device according to claim 1, wherein each charge retaining section and each gate electrode are electrically connected to a contact arranged to face the first surface of the corresponding element region.

8. The light detecting device according to claim 3, comprising:
a first shared connection section electrically connected to the charge retaining sections of two or more element regions; and
a first electrode electrically connected to the first shared connection section, wherein
the first shared connection section is arranged to be superimposed on each of the two or more charge retaining sections at positions facing the first surfaces of the element regions, or is arranged between the two or more charge retaining sections.

9. The light detecting device according to claim 1, wherein
the photoelectric converting section has a first-conductivity-type well region and a second-conductivity-type region that is of a second conductivity type and forms a pn junction with the well region,
the well region is exposed on a side of the light incidence surface of the element region,
a well electrode that is formed to face the light incidence surfaces of the element regions and is arranged along the trench section such that the well electrode closes an opening of the trench section on a side of the light incidence surfaces is provided, and
the well electrode is electrically connected to a portion of the well region which portion is exposed on the side of the light incidence surface of each element region.

10. The light detecting device according to claim 1, wherein
the photoelectric converting section has a first-conductivity-type well region and a second-conductivity-type region that is of a second conductivity type and forms a pn junction with the well region,
the well region is exposed on a side of the light incidence surface of the element region, and
a well contact that is formed to face the light incidence surface of the element region and is electrically connected to a portion of the well region which portion is exposed on the side of the light incidence surface of the element region is provided.

11. The light detecting device according to claim 1, wherein
the photoelectric converting section has a first-conductivity-type well region and a second-conductivity-type region that is of a second conductivity type and forms a pn junction with the well region,
the well region is exposed on a side of the first surface of the element region, and,
on the first surface of the element region, the gate electrode is formed to exclude not only the first region but also a second region that is a part of a region where the well region is formed.

12. The light detecting device according to claim 11, wherein each well region is electrically connected to a well contact arranged to face the first surface of the corresponding element region.

13. The light detecting device according to claim 11, comprising:
a second shared connection section electrically connected to the well regions of two or more element regions; and
a second electrode electrically connected to the second shared connection section, wherein
the second shared connection section is arranged to be superimposed on each of the two or more well regions at positions facing the first surfaces of the element regions, or is arranged between the two or more well regions.

14. The light detecting device according to claim 11, wherein an area of the second region is greater than an area of the first region.

15. The light detecting device according to claim 1, wherein the gate electrode has a vertical electrode section reaching a predetermined depth in the element region from the first surface of the element region.

16. The light detecting device according to claim 1, wherein the gate electrode reaches, from the first surface of the semiconductor substrate, a position located deeper than an end of the charge retaining section on a side of the second surface.

17. The light detecting device according to claim 1, wherein a groove width of a portion of side wall surfaces of the trench section which portion is covered with the gate electrode is larger than a groove width of a portion of the side wall surfaces of the trench section which portion is not covered with the gate electrode.

18. The light detecting device according to claim 1, comprising:
a first substrate having the semiconductor substrate; and
a second substrate stacked on the first substrate, the second substrate having pixel transistors that read out charge retained in the charge retaining sections of the semiconductor substrate, wherein
the charge retaining sections and the pixel transistors are electrically connected to each other via electrodes that extend in a thickness direction of the first substrate and reach the second substrate from the first substrate.

19. The light detecting device according to claim 1, comprising:
a first substrate having the semiconductor substrate; and
a second substrate stacked on the first substrate, the second substrate having pixel transistors that read out charge retained in the charge retaining sections of the semiconductor substrate, wherein
the first substrate has a wiring layer arranged on a surface of the semiconductor substrate on a side of the second substrate, and
the charge retaining sections and the pixel transistors are electrically connected to each other via wires in the wiring layer of the first substrate and electrodes that extend in a thickness direction of the first substrate and reach the second substrate from the wiring layer.

20. The light detecting device according to claim 1, comprising:
a first substrate having the semiconductor substrate; and
a second substrate stacked on the first substrate, the second substrate having pixel transistors that read out charge retained in the charge retaining sections of the semiconductor substrate, wherein
the charge retaining sections and the pixel transistors are electrically connected to each other via multiple first electrode pads arranged on a surface of the first substrate on a side of the second substrate and multiple second electrode pads that are arranged on a surface of the second substrate on a side of the first substrate and are joined with the respective first electrode pads.

21. The light detecting device according to claim 1, wherein, when a predetermined voltage is applied, the gate electrode deepens potential in the entire element region excluding a region where the charge retaining section is formed, at a depth position where the gate electrode is arranged.

22. An electronic apparatus comprising:
a light detecting device including
a semiconductor substrate,
a trench section that partitions the semiconductor substrate into multiple element regions,
a photoelectric converting section that is formed in each element region and generates and stores charge according to a light reception amount,
a charge retaining section that is formed in each element region and retains charge generated in the photoelectric converting section, and
a transfer transistor that transfers, to the charge retaining section, charge stored in the photoelectric converting section,
the charge retaining section being formed to reach a predetermined depth in the element region from a first surface of the element region that is a surface opposite to a light incidence surface of the element region, and
the transfer transistor having a gate electrode that continuously covers at least a part of the first surface of the element region excluding a first region that is on the first surface and is a region where the charge retaining section is formed, and at least a part of a second surface that is a surface of the element region on a side of the trench section.
